(19) United States
(12) Patent Application Publication
(10) Pub. No.: US 2008/0206997 A1
(43) Pub. Date: Aug. 28, 2008

(54) Method for Manufacturing Insulating Film and Method for Manufacturing Semiconductor Device

(75) Inventor: Teruyuki Fujii, Atsugi (JP)

Correspondence Address: COOK, ALEX, McFARRON, MANZO, CUMMINGS & MEHLER,;LTD., 200 WEST ADAMS STREET, SUITE 2850, CHICAGO, IL, 60606, US

(73) Assignee: Semiconductor Energy Laboratory Co., Ltd.

(21) Appl. No.: 12/029,079

(22) Filed: Feb. 11, 2008

(30) Foreign Application Priority Data
Feb. 26, 2007 (JP) 2007-045146

(51) Int. Cl. H01L 21/311

(52) U.S. Cl. 438/694; 257/E21.249

(57) ABSTRACT

A method for manufacturing an insulating film, by which the insulating film can be formed of a non-photosensitive siloxane resin and formed into a desired shape by wet etching. A thin film is formed with a suspension in which a siloxane resin or a siloxane-based material is included in an organic solvent; a first heat treatment is performed on the thin film; a mask is formed over the thin film after the first heat treatment; wet etching with an organic solvent is performed to process the shape of the thin film after the first heat treatment; and a second heat treatment is performed on the processed thin film.

### BACKGROUND OF THE INVENTION

1. Field of the Invention

The present invention relates to a method for manufacturing an insulating film processed into a desired shape. In addition, the present invention relates to a method for manufacturing a semiconductor device in which the insulating film is used as an interlayer film.

2. Description of the Related Art

As for an insulating film provided in a semiconductor element or between wirings, it is important to have, in addition to low permittivity, flatness on its surface in order to uniformly perform photolithography or etching of each film formed over the insulating film or improve coverage with each film in a step of the insulating film. In the point of surface flatness, a higher quality insulating film can be formed easily by a coating method (SOD: Spin On Deposition) rather than by a CVD method. In particular, an insulating film formed of a siloxane resin by a coating method has been widely used as an insulating film of an integrated circuit since it has advantages of low permittivity and good heat resistance in addition to high flatness.

A siloxane resin corresponds to a resin including a Si—O—Si bond formed using a siloxane-based material as a starting material. For the siloxane resin which has high chemical resistance, wet etching is not suited but processing by dry etching is the mainstream for processing (patterning) into a desired shape. In Reference 1 (: Japanese Published Patent Application No. Hei7-133350), patterning of a siloxane resin by dry etching has been described.

Further, a technique by which photosensitivity is provided for a siloxane resin which is originally non-photosensitive with the use of molecular design has been studied in recent years. With the siloxane resin having photosensitivity, patterning of a siloxane resin by a photolithography method can be performed. In Reference 2 (: Japanese Published Patent Application No. 2007-17481), a siloxane resin having photosensitivity has been described.

### SUMMARY OF THE INVENTION

However, in the case where an insulating film formed of a siloxane resin is patterned by dry etching, the taper angle of a cross-sectional surface tends to be large. If the taper angle is large, in an edge of the insulating film formed of a siloxane resin, a problem such as extreme thinning or disconnecting of a wiring or a film formed to be in contact with the insulating film tends to occur.

OLED (organic light emitting diode) which is one of light-emitting elements is an element for which flatness of an insulating film is very important. A light-emitting element includes typically a pair of electrodes and a layer (hereinafter referred to as an electroluminescent layer) containing an electroluminescence material from which electroluminescence generated by application of an electric field can be obtained, which is provided between the electrodes. If an insulating film does not have sufficiently high flatness, the electrode of the light-emitting element formed over the insulating film has roughness, and a problem of locally and extremely thinning, disconnecting due to a step, or the like of the electroluminescent layer formed over the electrode tends to occur. Further, deterioration of the electroluminescence material tends to be increased in the extremely thin portion of the electroluminescent layer, which causes reduction of reliability of the light-emitting element. Further, since the pair of electrodes is short-circuited in a portion where the electroluminescent layer is disconnected due to a step, the light-emitting element does not emit light or deterioration of the electroluminescence material tends to be increased from the periphery of the short-circuited portion, which causes reduction of reliability of the light-emitting element.

In addition, when the insulating film formed of a siloxane resin is patterned by dry etching, there is also a problem in that OH radicals tend to be generated on the surface of the insulating film formed of a siloxane resin by plasma generated at the time of etching. If OH radicals are increased, the hygroscopicity of the insulating film is increased and moisture in the insulating film may adversely affect the reliability of a semiconductor element. In particular, the deterioration of the electroluminescence material used in the above-described light-emitting element is increased by moisture. Therefore, the degree of hygroscopicity in the insulating film is a big issue by which the reliability of a semiconductor device is determined.

On the other hand, in the case where a siloxane resin having photosensitivity is used, the above-described problems which occur in the case of employing dry etching can be avoided since the siloxane resin is patterned by a photolithography method. However, the siloxane resin having photosensitivity is currently under development for various uses, and inexpensive products thereof have not penetrated the market yet.

In view of the foregoing problems, it is an object of the present invention to provide a method for manufacturing an insulating film, by which the insulating film can be formed of a conventional non-photosensitive siloxane resin and formed into a desired shape by wet etching. In addition, it is an object of the present invention to provide a method for manufacturing a semiconductor device, in which the above-described manufacturing method is used.

The present inventor found that wet etching using an organic solvent can be performed not after an insulating film is formed of a siloxane resin but in the process for forming an insulating film of a siloxane resin. In the present invention, a thin film including a siloxane resin or a siloxane-based material which is a precursor of a siloxane resin is burned, and wet etching is performed on the thin film by an organic solvent before the thin film is completed as an insulating film.

Specifically, in the present invention, heat treatment is performed at least twice in the process for forming an insulating film of a siloxane resin. The wet etching with an organic solvent is performed between the two heat treatments. The first heat treatment (baking) is performed after a thin film is formed with a suspension including a siloxane resin or a siloxane-based material which is a precursor of a siloxane resin. Owing to this baking, the siloxane-based material in the thin film is gelled and/or the organic solvent contained in the thin film partially vaporizes, whereby the thin film is hardened as much as wet etching can be performed. Then, the thin film hardened by baking is processed into a desired shape by wet etching with an organic solvent. The second heat treatment (curing) is performed after the wet etching. Owing to this curing, the gelled siloxane-based material in the thin film is polymerized and/or the organic solvent contained in the thin film further vaporizes, whereby an insulating film of a siloxane resin having a desired pattern is formed.

As the organic solvent used for the etching, medium alcohol in which the carbon number is in the range of 3 to 5, such as butanol or propanol is preferable. By using the above-described alcohol as an etchant, the etching rate suitable for etching and high selection ratio with respect to a mask can be obtained when wet etching is performed on the thin film which has been hardened by baking. Further, by using such an organic solvent as an etchant, unlike the case where an inorganic material such as hydrofluoric acid is used as an etchant, roughness of the surface of a conductive film such as a wiring, an electrode, or the like under the insulating layer can be suppressed and the risk for handling can be reduced.

Processing temperature of baking is set to the temperature in the range enough to harden the thin film including a siloxane resin or a siloxane-based material as much as selective wet etching can be performed. Specifically, the temperature is set to be as high as a desired etching rate can be provided but lower than the boiling point of the organic solvent contained in the suspension for forming the thin film.

Further, the processing temperature of curing is set to the temperature in the range enough to polymerize the siloxane-based material contained in the thin film and/or promote volatilization of the organic solvent contained in the thin film. Specifically, the temperature of curing is set to be higher than the boiling point of the organic solvent contained in the suspension for forming the thin film.

Note that the mask used for performing selective wet etching may be formed by a photolithography method or either a droplet discharging method or a printing method. Note that the droplet discharging method means a method in which droplets containing predetermined composition are discharged or spouted out from a pore to form a predetermined pattern, and includes an ink jetting method in the category.

According to the method for manufacturing an insulating film of the present invention, since wet etching can be used, the taper angle in edge of a patterned insulating film can be suppressed to be small and an insulating film having higher flatness can be formed. Further, according to the method for manufacturing an insulating film of the present invention, a problem in that the hygroscopicity of an insulating film is increased by increase of OH radicals does not occur unlike the case of dry etching. Furthermore, since an insulating film can be formed of a conventional non-photosensitive siloxane resin, an inexpensive raw material can be used.

Further, according to the method for manufacturing a semiconductor device of the present invention, in which the above-described manufacturing method of an insulating film is used, by suppressing the taper angle in the edge of an insulating film to be small, extremely thinning or disconnecting a wiring or a film in the edge of the insulating film, formed to be in contact with the insulating film can be prevented. Therefore, the yield and/or reliability of a semiconductor device can be increased. Further, in the case of a semiconductor device having a light-emitting element, by suppressing the taper angle in the edge of an insulating film to be small, an electroluminescent layer can be prevented from being partially thinning extremely or disconnecting due to a step. Therefore, the reliability of a light-emitting element, and then the reliability of a semiconductor device having the light-emitting element can be improved.

Further, according to the method for manufacturing a semiconductor device of the present invention, in which the above-described manufacturing method of an insulating film is used, since the problem in that hygroscopicity of an insulating film is increased by increase of OH radicals does not occur unlike the case of dry etching, the reliability of a light-emitting element and then the reliability of a semiconductor device can be prevented from being adversely affected by moisture in the insulating film. In addition, in the case of a semiconductor device having a light-emitting element, the deterioration of the light-emitting element can be suppressed by suppressing the hygroscopicity of an insulating film, whereby the reliability of the semiconductor device can be improved.

Furthermore, according to the method for manufacturing a semiconductor device of the present invention, in which the above-described manufacturing method of an insulating film is used, since the insulating film can be formed of a conventional non-photosensitive siloxane resin, an inexpensive raw material can be used, whereby the manufacturing cost of the semiconductor device can be suppressed.

### BRIEF DESCRIPTION OF THE DRAWINGS

FIGS. 1A to 1C are diagrams showing a method for manufacturing an insulating film of the present invention.

FIGS. 2A to 2C are diagrams showing a method for manufacturing an insulating film of the present invention.

FIGS. 3A to 3C are diagrams showing a method for manufacturing an insulating film of the present invention.

FIGS. 4A to 4C are diagrams showing a method for manufacturing an insulating film of the present invention.

FIGS. 5A to 5C are diagrams showing a method for manufacturing a semiconductor device of the present invention.

FIGS. 6A and 6B are diagrams showing a method for manufacturing a semiconductor device of the present invention.

FIGS. 7A and 7B are diagrams showing a method for manufacturing a semiconductor device of the present invention.

FIGS. 8A and 8B are diagrams showing a method for manufacturing a semiconductor device of the present invention.

FIG. 9 is a diagram showing a method for manufacturing a semiconductor device of the present invention.

FIGS. 10A to 10C are diagrams showing a method for manufacturing a semiconductor device of the present invention.

FIGS. 11A to 11C are diagrams showing a method for manufacturing a semiconductor device of the present invention.

FIGS. 12A to 12C are diagrams showing a method for manufacturing a semiconductor device of the present invention.

FIGS. 13A to 13C are diagrams showing a method for manufacturing a semiconductor device of the present invention.

FIGS. 14A and 14B are diagrams showing a method for manufacturing a semiconductor device of the present invention.

FIGS. 15A and 15B are diagrams showing a method for manufacturing a semiconductor device of the present invention.

FIGS. 16A and 16B are diagrams showing a method for manufacturing a semiconductor device of the present invention.

FIGS. 17A to 17C are diagrams showing a method for manufacturing a semiconductor device of the present invention.

FIGS. 18A to 18C are cross-sectional diagrams of a semiconductor device manufactured using the present invention.

FIGS. 19A to 19C are cross-sectional diagrams of a semiconductor device manufactured using the present invention.

### DETAILED DESCRIPTION OF THE INVENTION

Hereinafter, embodiment modes and embodiments of the present invention are described using drawings. However, the present invention can be implemented with many different modes, and it is easily understood by those skilled in the art that the mode and details of the present invention can be changed variously unless such changes depart from the spirit and scope of the present invention. Thus, the present invention is construed without limiting to the description of the embodiment modes and embodiments included in this specification.

### Embodiment Mode 1

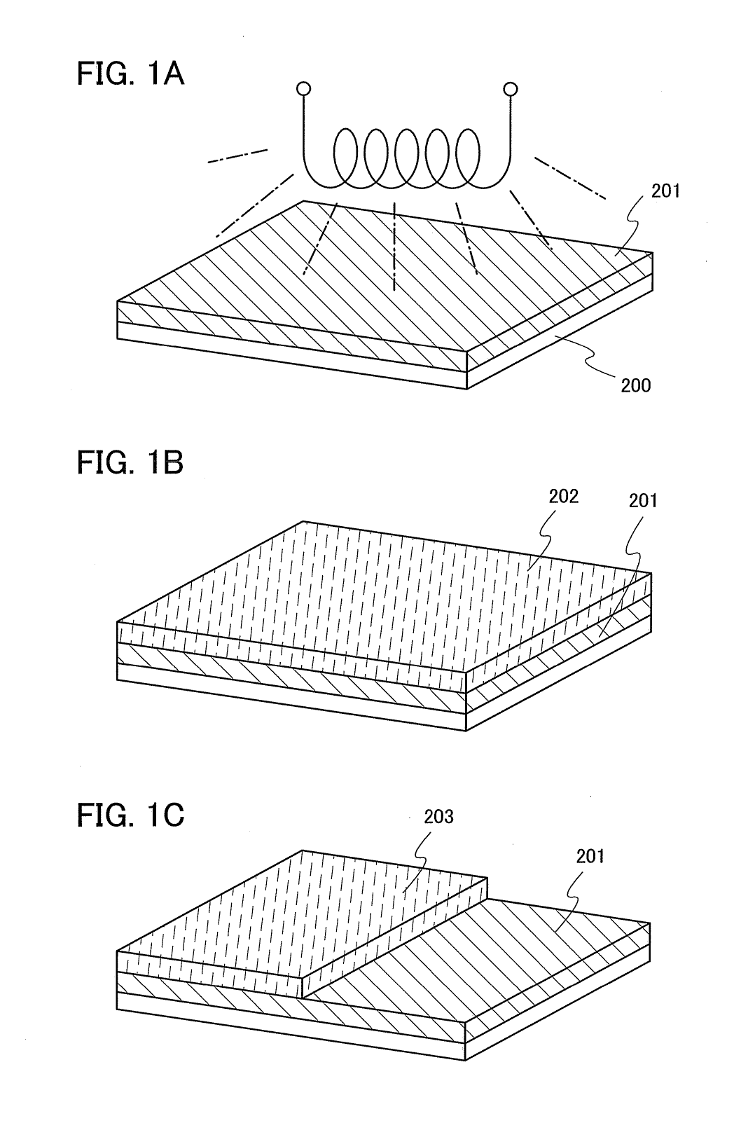

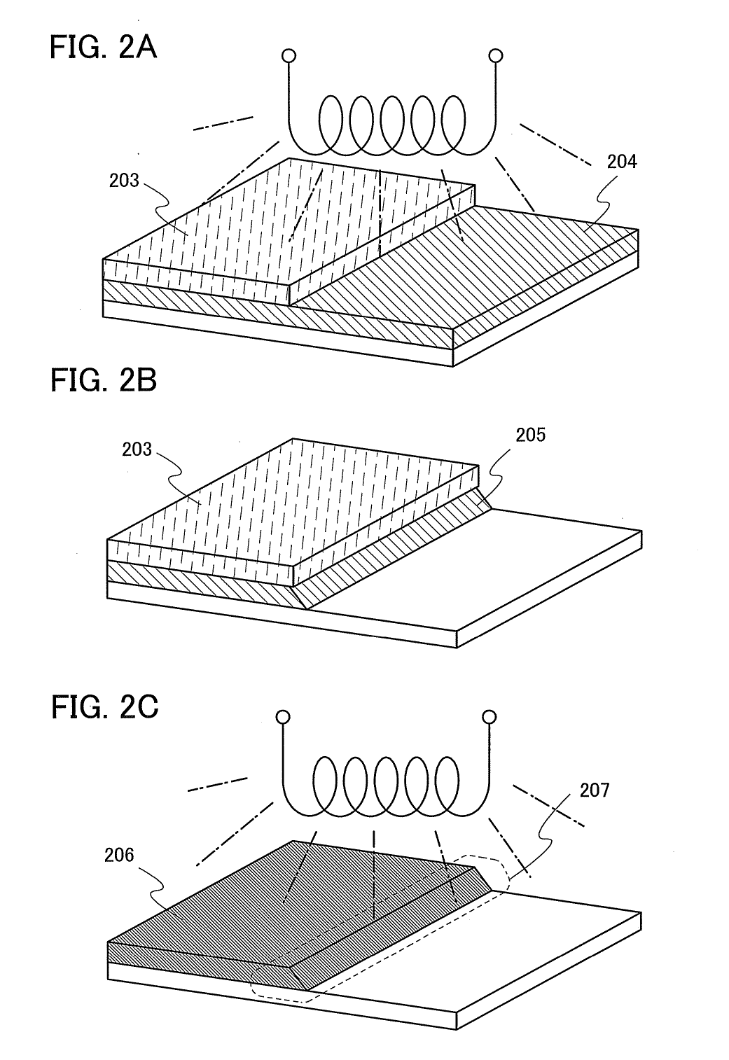

In this embodiment mode, a method for manufacturing an insulating film of the present invention in which a photolithography method is used is described using FIGS. 1A to 1C and 2A to 2C. First, as shown in FIG. 1A, a suspension in which a siloxane resin or a siloxane-based material which is a precursor of a siloxane resin is dispersed is applied over a substrate 200, to form a thin film 201. Siloxane resin is a material in which a skeleton structure is constructed by the bond of silicon (Si) and oxygen (O). As a substituent, at least one kind selected from fluorine, a fluoro group, an organic group (e.g., an alkyl group or an aromatic hydrocarbon) may be used in addition to hydrogen.

A solvent of the suspension is preferably an organic solvent into which a siloxane resin or a siloxane-based material can be dispersed; for example, propylene glycol monomethyl ether acetate (PGMEA), 3-methoxy-3-methyl-1-butanol (MMB), N-methyl-2-pyrrolidone (NMP), or the like can be used. In this embodiment mode, propylene glycolmonomethyl ether acetate (PGMEA) and 3-methoxy-3-methyl-1-butanol (MMB) are used. The application of a suspension can be performed by a spin-coating method in which the suspension is dropped on the substrate 200 and then the substrate 200 is rapidly spun. Further, other than the spin-coating method, a slit-coating method, a dip-coating method, or the like may be used as well to perform the application of a suspension.

Note that, although the case where the thin film 201 is directly formed on the substrate 200 is shown in FIG. 1A, the present invention is not limited to this structure. The thin film 201 containing a siloxane resin or a siloxane-based material may be formed as well after various films such as a conductive film including a wring or an electrode in addition to an insulating film are formed over the substrate 200.

Next, heat treatment called prebaking is performed on the thin film 201 to harden the thin film 201. In this embodiment mode, by performing the prebaking, working property in a process after a mask is formed by a photolithography method can be improved.

It is preferable that the temperature of prebaking be as high as the thin film 201 can be hardened for good workability but lower than the boiling point of the organic solvent in the thin film 201. In this embodiment mode, prebaking is performed at temperatures of 90° C. to 100° C. for 30 seconds to 60 seconds.

Next, the thin film 201 is exposed to liquid developer to improve the adhesion between the thin film 201 and a resist. Then, as shown in FIG. 1B, a resist layer 202 is formed on the thin film 201 by using a resist. In this embodiment mode, a novolac resin is used as the resist. Then, heat treatment (prebaking of resist) at 110° C. to 120° C. for 30 seconds to 90 seconds is performed on the resist layer 202. With the above-described heat treatment, a less soluble layer is formed in the surface to harden the resist layer 202, whereby working property can be improved.

Next, the resist layer 202 is exposed to light and developed to remove part of the resist layer 202. Accordingly, as shown in FIG. 1C, a mask 203 provided selectively over the thin film 201 is formed.

Then, as shown in FIG. 2A, heat treatment called baking is performed to further harden the thin film 201. In FIG. 2A, the thin film 201 after being subjected to the baking is shown as a thin film 204.

Here, results of an etching rate (nm/min) of each of the thin film and the resist according to condition of baking and kind of etchant are shown in Table 1.

TABLE 1

| | ethanol | | OK73 thinner | | acetone | | 2-butanol | |
|---|---|---|---|---|---|---|---|---|
| | resist | thin film | resist | thin film | resist | thin film | resist | thin film |
| heating-free | | | | | | | 2.284 | 100< |
| 130° C. | | | | | | | 0.114 | 16.115 |
| 0.5 hour | | | | | | | | |
| 135° C. | 42.349 | 22.201 | 17.397 | 11.903 | 39.657 | 15.627 | −0.068 | 13.028 |
| 0.5 hour | | | | | | | | |
| 140° C. | 23.557 | 12.454 | 17.008 | 8.604 | 24.315 | 10.95 | −0.03 | 4.58 |
| 0.5 hour | | | | | | | | |
| 150° C. | 12.956 | 5.008 | 8.603 | 4.334 | 15.906 | 5.831 | −0.088 | 2.716 |
| 0.5 hour | | | | | | | | |
| 160° C. | 2.988 | 2.649 | 1.801 | 0.271 | 5.086 | 3.275 | −0.058 | 1.33 |
| 0.5 hour | | | | | | | | |
| 180° C. | 0.018 | 0.409 | 0.041 | 0.019 | 2.379 | 0.865 | | |
| 0.5 hour | | | | | | | | |

unit is nm/s

In any sample, a thin film was formed by application of a suspension in which a siloxane resin or a siloxane-based material is dispersed into an organic solvent to a substrate and then prebaking at 90° C. for 90 seconds was performed to the thin film to harden the thin film. After the prebaking was performed, baking was performed to each sample according to each condition of temperature, or the baking was not performed, and then wet etching was performed thereto at room temperature.

The used siloxane resin or siloxane-based material was PSB-K31 produced by Toray Industries, Inc., and the siloxane resin or siloxane-based material was contained at the rate of 15 to 25 wt % in 3-methoxy-3-methyl-1-butanol (MMB) which is a solvent. The above-described siloxane-based material was further dispersed into propylene glycolmonomethyl ether acetate (PGMEA). Novolac resin was used as the resist. As the etchants, Ethanol, OK73 thinner (produced by Tokyo Ohka Kogyo Co., Ltd), acetone, and 2-butanol were used. OK73 thinner contains propylene glycolmonomethyl ether (PGME) and propylene glycolmonomethyl ether acetate (PGMEA) so that the weight ratio is 7:3.

Baking was performed for 0.5 hours to all of the samples other than the “heating-free” sample to which backing was not performed. Temperatures of the baking were set to 130° C., 135° C., 140° C., 150° C., 160° C., and 180° C.

As shown in Table 1, in the samples using ethanol, OK73 thinner, and acetone as the etchants, the etching rate of the thin film was smaller than that of the resist regardless of the condition of baking. However, in the samples using 2-butanol as the etchant, the etching rate of the thin film was larger than that of the resist. Therefore, from the results shown in Table 1, it was found that 2-butanol is the most suitable as the etchant of the thin film containing a siloxane-based material, among the organic solvents.

Further, in the samples using 2-butanol as the etchant, the etching rate of the resist was negative in the conditions of baking of 135° C., 140° C., 150° C., and 160° C. It can be considered that this is due to resist swelling and thus etching of the resist was not performed in these samples. Among the above-described samples, the etching rate of the thin film was the highest in the sample in the condition of baking of 135° C., and the etching rate of the thin film was decreased as the temperature of baking became higher.

Therefore, considering only the samples using 2-butanol as the etchants, it can be found that the temperature of baking which is too high can keep the difference of etching rate as much as pattern formation can be performed but is not suited for the condition of etching since the etching rate of the thin film is too low. Therefore, it is preferable that the temperature of baking be lower than the boiling point of an organic solvent used for a suspension.

Furthermore, the etching rate of the resist was positive in the sample in the condition of baking of 130° C. and the heating-free sample. In particular, in the heating-free sample, the etching rate of the resist was 2.284 nm/s which is relatively high. Further, the heating-free sample which was etched using 2-butanol, the etching rate of the thin film was difficult to be measured correctly because it was too high, and therefore, it is guessed that the thin film was actually etched at over 100 nm/s.

Therefore, when considering only the samples using 2-butanol as the etchants, it can be found that if the temperature of baking is too low, not only the etching rate of the resist but also the etching rate of the thin film becomes too high. If the etching rate is too high, the minimal travel time of a substrate between equipment, which is needed from wet etching to washing out of etchant cannot be obtained; therefore, it can be found that it is not suited for the etching condition. Therefore, the temperature of baking is preferably set to the temperature as high as the thin film can be hardened such that the period of time up to completion of etching is 30 seconds or longer regardless of thickness of the thin film. Alternatively, by setting the lower limit of the temperature of baking to a temperature which is lower than the boiling point of a solvent by 70° C., the thin film can be hardened as much as a desired etching rate is provided.

Accordingly, in the case where propylene glycolmonomethyl ether acetate (PGMEA) and 3-methoxy-3-methyl-1-butanol (MMB) are used as organic solvents in which a siloxane resin or a siloxane-based material is dispersed and 2-butanol is used as an etchant in a later etching process, it is guessed that the baking temperature is preferably about 100° C. to 170° C. when considering the etching rate of the thin film and the difference of etching rate between the resist and the thin film.

In view of the above-described experimental results, in this embodiment mode, baking was performed at 130° C. to 140° C. for 0.5 hours to 1 hour.

Owing to baking, the mask 203 can be prevented from being fretted or solved by the organic solvent used in later wet etching.

Next, as shown in FIG. 2B, an organic solvent is used as an etchant to perform wet etching of the thin film 204. As the organic solvent used as the etchant, medium alcohol in which the carbon number is in the range of 3 to 5, such as butanol or propanol is preferable. By using the above-described alcohol as an etchant, the etching rate suitable for etching and high selection ratio with respect to the mask 203 can be obtained when wet etching is performed on the thin film 204 which has been hardened by baking. Further, by using such an organic solvent as an etchant, unlike the case where an inorganic material such as hydrofluoric acid is used as an etchant, roughness of the surface of a conductive film such as a wiring, an electrode, or the like under the thin film 204 can be suppressed and the risk for handling can be reduced.

In this embodiment mode, 2-butanol is used as the etchant to perform wet etching. By the wet etching, a thin film 205 which has been processed (patterned) into a desired shape can be formed.

Next, the mask 203 is removed. As a stripper for removing the mask 203, the one which can selectively remove the mask 203 is used. For example, in the case where the mask 203 is formed of a novolac resin, a stripper containing 2-aminoethanol and glycol ether can be used.

Next, as shown in FIG. 2C, heat treatment called curing is performed on the thin film 205. Process temperature of curing is set to the temperature in the range enough to polymerize a siloxane-based material contained in the thin film 205 and/or promote vaporization of the organic solvent contained in the thin film 205. Specifically, the temperature of curing is set to be higher than the boiling point of the organic solvent contained in the suspension for forming the thin film 201.

In this embodiment mode, curing is performed at 300° C. to 350° C. for about 1 hour. Owing to this curing, the siloxane-based material in the thin film 205 is polymerized and/or the organic solvent contained in the thin film 205 further vaporizes than the case of baking, whereby an insulating film 206 of a siloxane resin having a desired pattern is formed.

By the above-described manufacturing method, the taper angle in the edge of the insulating film 206 can be suppressed, that is, the gradient of an edge 207 can be suppressed. Further, according to the above-described method for manufacturing an insulating film, a problem in that the hygroscopicity of an insulating film is increased by increase of OH radicals does not occur unlike the case of dry etching. Furthermore, since an insulating film can be formed of a conventional non-photosensitive siloxane resin, an inexpensive raw material can be used.

Furthermore, in the manufacturing method of this embodiment mode, baking for hardening a thin film can prevent the mask 203 from being fretted or solved by an organic solvent, that is, the baking for hardening a thin film also functions as heat treatment for improving the organic solvent resistance of the mask 203.

This embodiment mode can be implemented combining with another embodiment mode as appropriate.

### Embodiment Mode 2

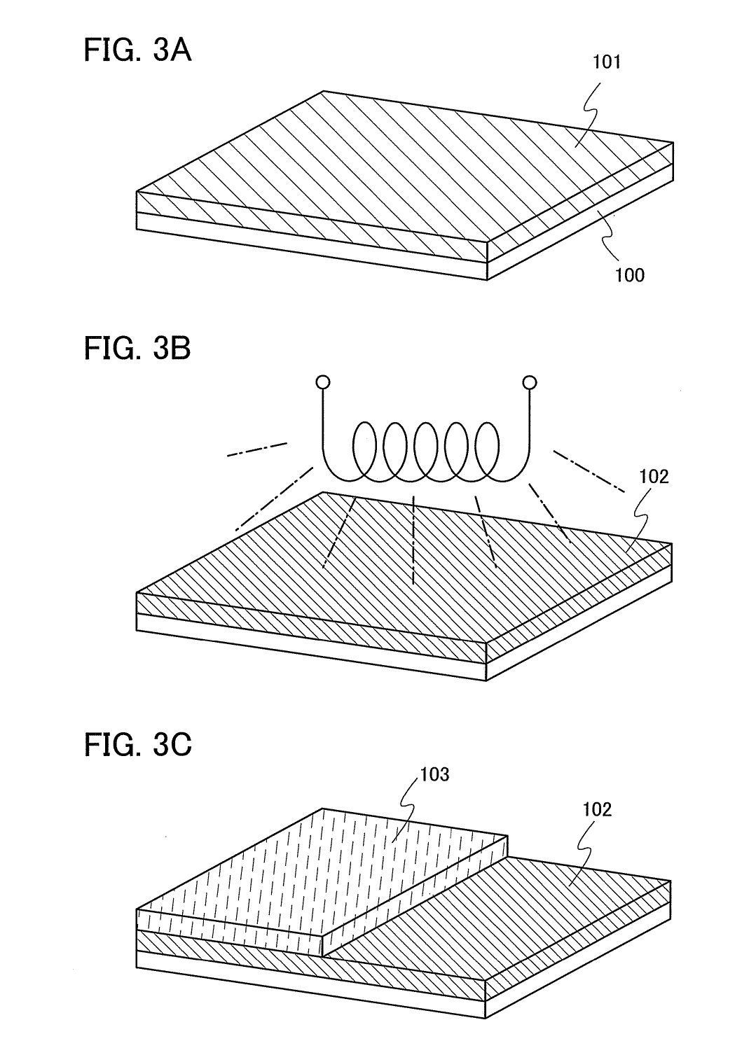

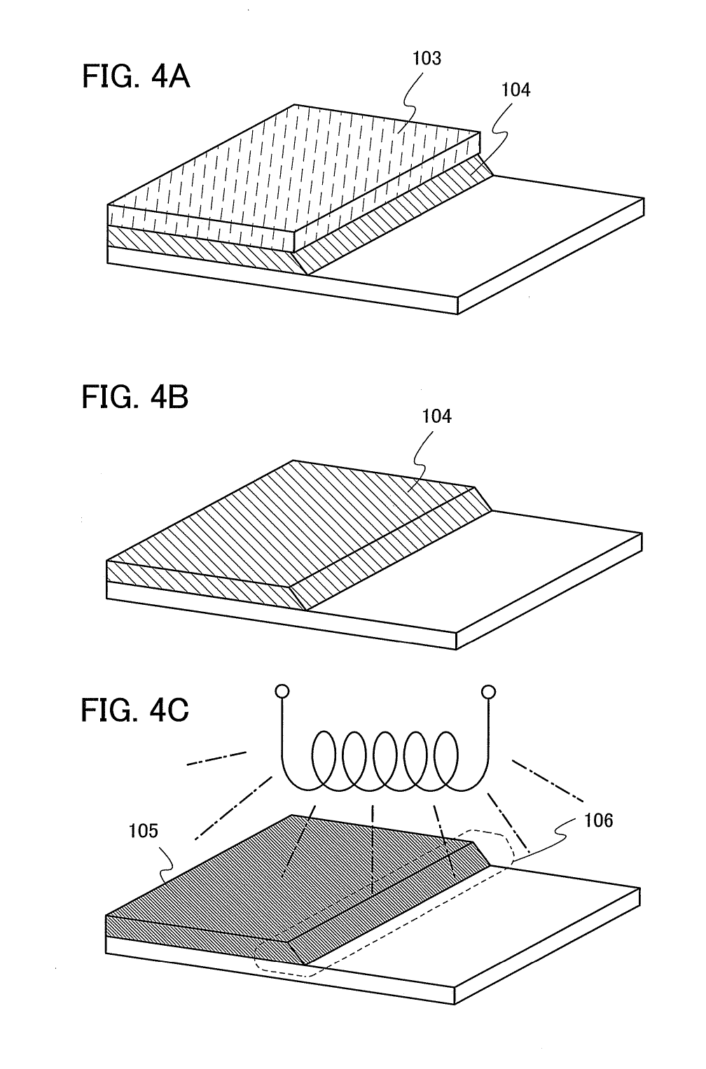

In this embodiment mode, a method for manufacturing an insulating film of the present invention is described using FIGS. 3A to 3C and 4A to 4C. First, as shown in FIG. 3A, similarly to Embodiment Mode 1, a suspension in which a siloxane resin or a siloxane-based material which is a precursor of a siloxane resin is dispersed is applied over a substrate 100, to form a thin film 101. Siloxane resin is a material in which a skeleton structure is constructed by the bond of silicon (Si) and oxygen (O). As a substituent, at least one kind selected from fluorine, a fluoro group, an organic group (e.g., an alkyl group or an aromatic hydrocarbon) may be used other than hydrogen.

A solvent of the suspension is preferably an organic solvent into which a siloxane resin or a siloxane-based material can be dispersed; for example, propylene glycol monomethyl ether acetate (PGMEA), 3-methoxy-3-methyl-1-butanol (MMB), N-methyl-2-pyrrolidone (NMP), or the like can be used. In this embodiment mode, propylene glycolmonomethyl ether acetate (PGMEA) and 3-methoxy-3-methyl-1-butanol (MMB) are used. The application of a suspension can be performed by a spin-coating method in which the suspension is dropped on the substrate 100 and then the substrate 100 is rapidly spun. Further, other than the spin-coating method, a slit-coating method, a dip-coating method, or the like may be used as well to perform the application of a suspension.

Note that, although the case where the thin film 101 is directly formed on the substrate 100 is shown in FIG. 3A, the present invention is not limited to this structure. The thin film 101 containing a siloxane resin or a siloxane-based material may be formed as well after various films such as a conductive film including a wring or an electrode in addition to an insulating film are formed over the substrate 100.

Next, heat treatment called prebaking may be performed to the thin film 101 before baking is performed. Prebaking is heat treatment for improving the working property. For example, in the case where equipment for forming the thin film 101 using a suspension is separated from equipment for performing baking or the like, the working efficiency can be improved by hardening the thin film 101 with prebaking in advance.

It is preferable that the temperature of prebaking be as high as the thin film 101 can be hardened for good workability but lower than the boiling point of the organic solvent in the thin film 101. In the case where propylene glycolmonomethyl ether acetate (PGMEA) and 3-methoxy-3-methyl-1-butanol (MMB) are used as organic solvents, prebaking may be performed at 90° C. to 100° C. for 30 seconds to 60 seconds.

Then, as shown in FIG. 3B, heat treatment called baking is performed to harden the thin film 101. In FIG. 3B, the thin film 101 after being subjected to the baking is shown as a thin film 102. Temperature of baking is set to the temperature in the range enough to harden the thin film 101 as much as selective wet etching can be performed. Specifically, the temperature is set to be as high as a desired etching rate can be provided but lower than the boiling point of the organic solvent contained in the suspension for forming the thin film 101. In this embodiment mode, baking is performed at 130° C. to 140° C. for 0.5 hours to 1 hour.

Next, as shown in FIG. 3C, a mask 103 is formed on the thin film 102 formed by baking. The mask 103 may be formed by a photolithography method using a resist or by either a droplet discharging method or a printing method.

Note that, although the mask 103 is formed after baking is performed in this embodiment mode, the present invention is not limited to this structure. Baking may be performed after the mask 103 is formed as well.

Further, either in the case of using a photolithography method or in the case of using a droplet discharging method or a printing method, heat treatment is performed in the process for forming the mask at least once. In the present invention, one heat treatment may also serve as baking.

Next, as shown in FIG. 4A, an organic solvent is used as an etchant to perform wet etching of the thin film 102. As the organic solvent used as the etchant, medium alcohol in which the carbon number is in the range of 3 to 5, such as butanol or propanol is preferable. By using the above-described alcohol as an etchant, the etching rate suitable for etching and high selection ratio with respect to the mask 103 can be obtained when wet etching is performed on the thin film 102 which has been hardened by baking. Further, by using such an organic solvent as an etchant, unlike the case where an inorganic material such as hydrofluoric acid is used as an etchant, roughness of the surface of a conductive film such as a wiring, an electrode, or the like under the thin film 102 can be suppressed and the risk for handling can be reduced.

In this embodiment mode, 2-butanol is used as the etchant to perform wet etching. By the wet etching, a thin film 104 which has been processed (patterned) into a desired shape can be formed.

Next, as shown in FIG. 4B, the mask 103 is removed. As a stripper for removing the mask 103, the one which can selectively remove the mask 103 is used. For example, in the case where the mask 103 is formed of a novolac resin, a stripper containing 2-aminoethanol and glycol ether can be used.

Next, as shown in FIG. 4C, heat treatment called curing is performed on the thin film 104. Process temperature of curing is set to the temperature in the range enough to polymerize a siloxane-based material contained in the thin film 104 and/or promote vaporization of the organic solvent contained in the thin film 104. Specifically, the temperature of curing is set to be higher than the boiling point of the organic solvent contained in the suspension for forming the thin film 101.

In this embodiment mode, curing is performed at 300° C. to 350° C. for about 1 hour. Owing to this curing, the siloxane-based material in the thin film 104 is polymerized and/or the organic solvent contained in the thin film 104 further vaporizes than the case of baking, whereby an insulating film 105 of a siloxane resin having a desired pattern is formed.

By the above-described manufacturing method, the taper angle in the edge of the insulating film 105 can be suppressed, that is, the gradient of an edge 106 can be suppressed. Further, according to the above-described method for manufacturing an insulating film, a problem in that the hygroscopicity of an insulating film is increased by increase of OH radicals does not occur unlike the case of dry etching. Furthermore, since an insulating film can be formed of a conventional non-photosensitive siloxane resin, an inexpensive raw material can be used.

### Embodiment Mode 3

Next, a specific method for manufacturing a semiconductor device of the present invention is described. Note that the case where a light-emitting element and a transistor are manufactured over the same substrate is given as an example for description in this embodiment mode.

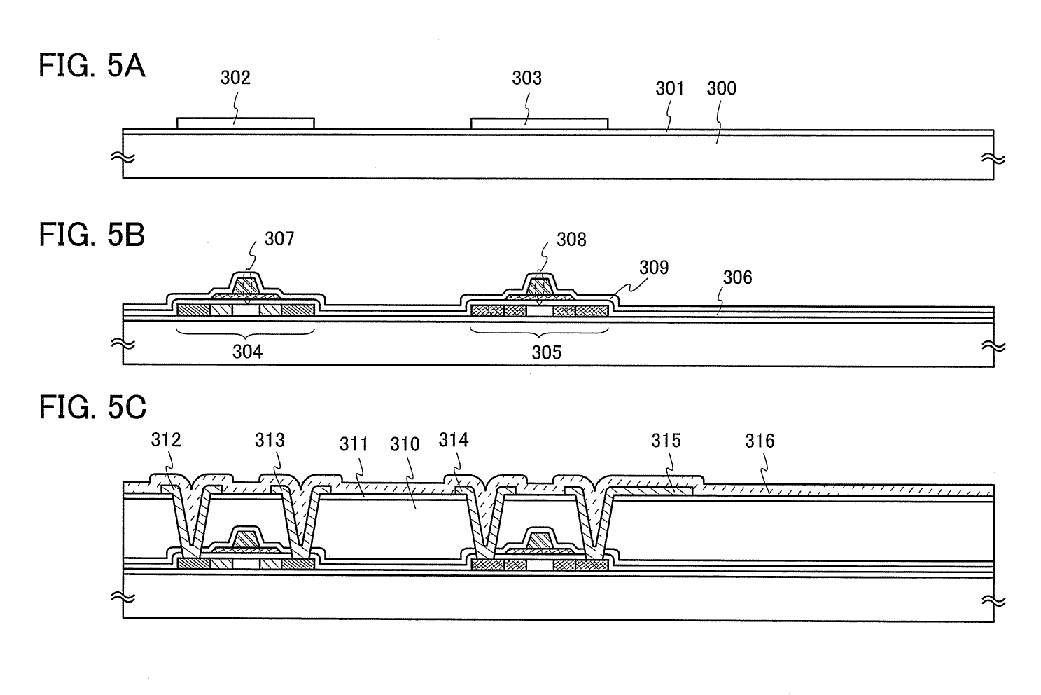

First, as shown in FIG. 5A, an insulating film 301 is formed over a substrate 300. As the substrate 300, for example, a glass substrate made of barium-borosilicate glass or alumino-borosilicate glass, a quartz substrate, a ceramic substrate, or the like can be used. Further, a metal substrate such as a stainless-steel substrate or a substrate in which an insulating film is formed on the surface of a silicon substrate may be used as well. A substrate made of a synthetic resin having flexibility such as plastics which generally has the heat-resistance temperature which is lower than those of the above-described substrates can be used as long as it can withstand the process temperature in a manufacturing process.

By provision of the insulating film 301, alkaline earth metal or alkali metal such as Na contained in the substrate 300 is prevented from being diffused into a semiconductor film and adversely affecting the characteristics of a semiconductor element such as a transistor. Therefore, the insulating film 301 is formed of silicon oxide, silicon nitride, silicon nitride oxide, or the like which can suppress the diffusion of alkali metal and alkaline earth metal into a semiconductor film. In this embodiment mode, a silicon nitride oxide film is formed to have a thickness of 10 to 400 nm (preferably 50 to 300 nm) by a plasma CVD method.

Note that the insulating film 301 may be either a single layer or a layer in which a plurality of insulating films are stacked. Further, in the case of using a substrate containing alkali metal or alkaline earth metal even if the amount thereof is small, such as a glass substrate, a stainless-steel substrate, or a plastic substrate, it is effective to provide the insulating film between the substrate and the semiconductor layer in point of preventing diffusion of impurities. However, the insulating film is not necessarily provided if the diffusion of impurities does not lead to any significant problem, such as in the case of using a quartz substrate.

Next, island-shaped semiconductor films 302 and 303 are formed over the insulating film 301. The thickness of each of the island-shaped semiconductor films 302 and 303 is 25 to 100 nm (preferably 30 to 60 nm). As each of the island-shaped semiconductor films 302 and 303, either an amorphous semiconductor or a polycrystalline semiconductor can be used. Further, as the semiconductor, not only silicon but also silicon germanium can be used. In the case of using silicon germanium, the concentration of germanium is preferably about 0.01 to 4.5 at. %.

In the case of using a polycrystalline semiconductor, an amorphous semiconductor is formed first, and a known crystallization method is applied to crystallize the amorphous semiconductor. As examples of the known crystallization method, a method for crystallizing by heating with a heater, a method for crystallizing by irradiation with laser light, a method for crystallizing with a catalytic metal, a method for crystallizing with infrared light, and the like can be given.

For example, when crystallization is performed with laser light, a pulsed oscillation type or continuous oscillation type excimer laser, YAG laser, YVO₄ laser, or the like may be used. For example, when a YAG laser is used, the second harmonic wave which is easy to be absorbed by a semiconductor film is preferably used. Then, the repetition rate is 30 to 300 kHz, the energy density is 300 to 600 mJ/cm² (typically 350 to 500 mJ/cm²), and the scanning rate may be set so as to irradiate each desired point by several shots.

Next, transistors are formed using the island-shaped semiconductor films 302 and 303. Note that, although top-gate type transistors 304 and 305 are formed using the island-shaped semiconductor films 302 and 303 as shown in FIG. 5B in this embodiment mode, each transistor is not limited to the top-gate type but a bottom-gate type may be employed as well.

Specifically, a gate insulating film 306 is formed to cover the island-shaped semiconductor films 302 and 303. Then, conductive films 307 and 308 which are processed (patterned) into a desired shape are formed over the gate insulating film 306. Then, impurities which impart n-type or p-type conductivity are added into the island-shaped semiconductor films 302 and 303 with the conductive films 307 and 308 or a resist which is patterned is used as a mask, whereby source and drain regions, impurity regions which function as LDD regions, or the like are formed. Note that a transistor 304 is an n-channel transistor and a transistor 305 is a p-channel transistor in this embodiment mode.

Note that, for the gate insulating film 306, silicon oxide, silicon nitride, silicon nitride oxide, or the like can be used. Further, as the forming method, a plasma CVD method, a sputtering method, or the like can be used. For example, in the case where a gate insulating film using silicon oxide is formed by a plasma CVD method, a gas in which TEOS (tetraethyl orthosilicate) and O₂ are mixed is used, the reaction pressure is set to 40 Pa, the substrate temperature is set to 300° C. to 400° C., and the high-frequency (13.56 MHz) power density is set to 0.5 to 0.8 W/cm².

Alternatively, aluminum nitride can be used for the gate insulating film 306. Aluminum nitride which has the thermal conductivity which is comparatively high can diffuse heat generated in a transistor effectively. Further alternatively, silicon oxide, silicon oxynitride, or the like containing no aluminum may be formed and then aluminum nitride may be stacked thereon to form a gate insulating film.

Through the above-described series of steps, the n-channel transistor 304 and the p-channel transistor 305 for controlling current to be supplied for a light-emitting element can be formed. Note that the method for manufacturing each transistor is not limited to the above-described process. A conductive film processed into a desired shape may be manufactured by a droplet discharging method as well.

Note that, although a thin film transistor is given as an example for description in this embodiment mode, the present invention is not limited to this structure. Other than a thin film transistor, a transistor formed using single-crystalline silicon, a transistor formed using an SOI, or the like can be used as well. Further, a transistor using an organic semiconductor or a transistor using a carbon nanotube may be used as well.

Next, an insulating film 309 is formed to cover the transistors 304 and 305. The insulating film 309 can be formed of an insulating film containing silicon made of silicon oxide, silicon nitride, silicon oxynitride, or the like to have a thickness of about 100 to 200 nm.

Next, heat treatment is performed to activate the impurity elements which have been added into the island-shaped semiconductor films 302 and 303. This step can use a thermal annealing method using an annealing furnace, a laser annealing method, or a rapid thermal annealing method (an RTA method). For example, activation is performed by a thermal annealing method in a nitrogen atmosphere in which the nitrogen concentration is 1 ppm or less, and preferably 0.1 ppm or less, at 400° C. to 700° C. (preferably 500° C. to 600° C.). Furthermore, hydrogenation of the island-shaped semiconductor films is performed by heat treatment at 300° C. to 450° C. for 1 to 12 hours in an atmosphere containing hydrogen at 3 to 100%. This step is performed for the purpose of termination of dangling bonds by thermally excited hydrogen. As another means for hydrogenation, plasma hydrogenation (using plasma-excited hydrogen) may be performed. Further, the activation treatment may be performed before the insulating film 309 is formed as well.

Next, as shown in FIG. 5C, insulating films 310 and 311 are formed to cover the insulating film 309. As the insulating film 310, an organic resin film, an inorganic insulating film, an insulating film containing a siloxane resin, or the like can be used. In this embodiment mode, an insulating film using polyimide is formed. As the insulating film 311, a film through which a matter which causes increase of deterioration of a light-emitting element such as moisture or oxygen penetrates in lesser amount than those of other insulating films is used. A silicon nitride film formed by an RF sputtering method is typically used, and a diamond like carbon (DLC) film or an aluminum nitride film can be used as well.

Next, the insulating films 309, 310 and 311 are etched to form openings. Then, conductive films 312 to 315 which connect to the island-shaped semiconductor films 302 and 303 are formed.

Next, a conductive film 316 having light-transmitting properties is formed to cover the insulating film 311 and the conductive films 312 to 315. In this embodiment mode, the conductive film 316 is formed of indium tin oxide (ITSO) containing silicon oxide by a sputtering method. Note that an oxide conductive material other than ITSO, such as indium tin oxide (ITO), zinc oxide (ZnO), indium oxide zinc (IZO), or gallium-doped zinc oxide (GZO) may be used for the conductive film 316 as well.

In the case of using ITSO, ITO in which silicon oxide is contained at 2 to 10 wt. % can be used as a target. Specifically, in this embodiment mode, a target in which In₂O₃, SnO₂, and SiO₂ are contained at 85:10:5 by wt. %, respectively, and the conductive film 316 is formed to have a thickness of 105 nm at an Ar gas flow of 50 sccm and an O₂ gas flow of 3 sccm, a sputtering pressure of 0.4 Pa, a sputtering power of 1 kW, and a film-formation speed of 30 nm/min.

After the conductive film 316 is formed, the surface thereof may be polished by a CMP method, cleaning with a polyvinyl alcohol series porous body, or the like so as to flatten the surface.

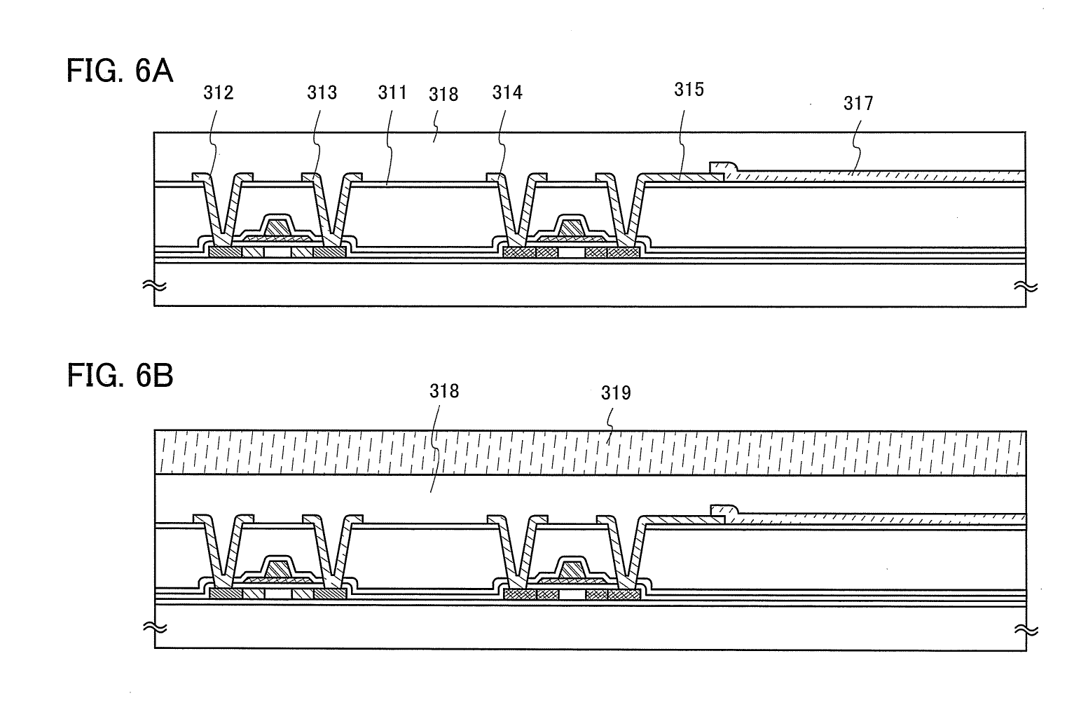

Next, as shown in FIG. 6A, the conductive film 316 is patterned so that an anode 317 which is connected to the conductive film 315 is formed.

Then a thin film 318 containing a siloxane resin or a siloxane-based material which is a precursor of a siloxane resin is formed to cover the insulating film 311, the conductive films 312 to 315, and the anode 317. The thin film 318 can be formed by application of a suspension into which a siloxane resin or a siloxane-based material is dispersed over the insulating film 311 to cover the conductive films 312 to 315 and the anode 317.

A solvent of the suspension is preferably an organic solvent into which a siloxane resin or a siloxane-based material can be dispersed; for example, propylene glycol monomethyl ether acetate (PGMEA), 3-methoxy-3-methyl-1-butanol (MMB), N-methyl-2-pyrrolidone (NMP), or the like can be used. In this embodiment mode, propylene glycolmonomethyl ether acetate (PGMEA) and 3-methoxy-3-methyl-1-butanol (MMB) are used. The application of a suspension can be performed by a spin-coating method in which the suspension is dropped on the insulating film 311 and then the substrate 300 is rapidly spun. Further, other than the spin-coating method, a slit-coating method, a dip-coating method, or the like may be used as well to perform the application of a suspension.

Next, heat treatment called prebaking is performed on the thin film 318 to harden the thin film 318. In this embodiment mode, by performing the prebaking, working property in a process after a mask is formed by a photolithography method can be improved. It is preferable that the temperature of prebaking be as high as the thin film 318 can be hardened for good workability but lower than the boiling point of the organic solvent in the thin film 318. In this embodiment mode, prebaking is performed at 90° C. to 100° C. for 30 seconds to 60 seconds.

Next, the thin film 318 is exposed to liquid developer to improve the adhesion between the thin film 318 and a resist. Then, as shown in FIG. 6B, a resist layer 319 is formed on the thin film 318 by using a resist. In this embodiment mode, a novolac resin is used as the resist. Then, heat treatment (prebaking of resist) at 110° C. to 120° C. for 30 seconds to 90 seconds is performed on the resist layer 319. With the above-described heat treatment, a less soluble layer is formed in the surface to harden the resist layer 319, whereby working property can be improved.

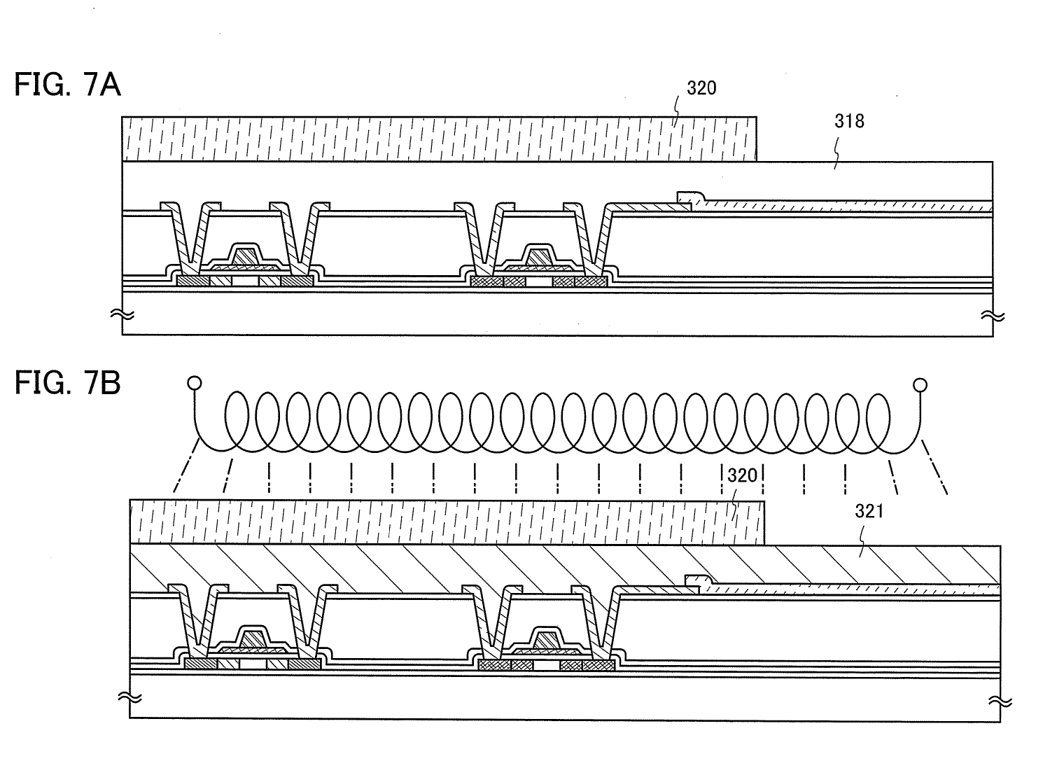

Next, the resist layer 319 is exposed to light and developed to remove part of the resist layer 319. Accordingly, as shown in FIG. 7A, a mask 320 provided selectively over the thin film 318 is formed.

Then, as shown in FIG. 7B, heat treatment called baking is performed to further harden the thin film 318. In FIG. 7B, the thin film 318 after being subjected to the baking is shown as a thin film 321. Temperature of baking is set to the temperature in the range enough to harden the thin film 318 as much as selective wet etching can be performed. Specifically, the temperature is set to be as high as a desired etching rate can be provided but lower than the boiling point of the organic solvent contained in the suspension for forming the thin film 318. In this embodiment mode, baking is performed at 130° C. to 140° C. for 0.5 hours to 1 hour.

Owing to baking, the mask 320 can be prevented from being fretted or solved by the organic solvent used in later wet etching.

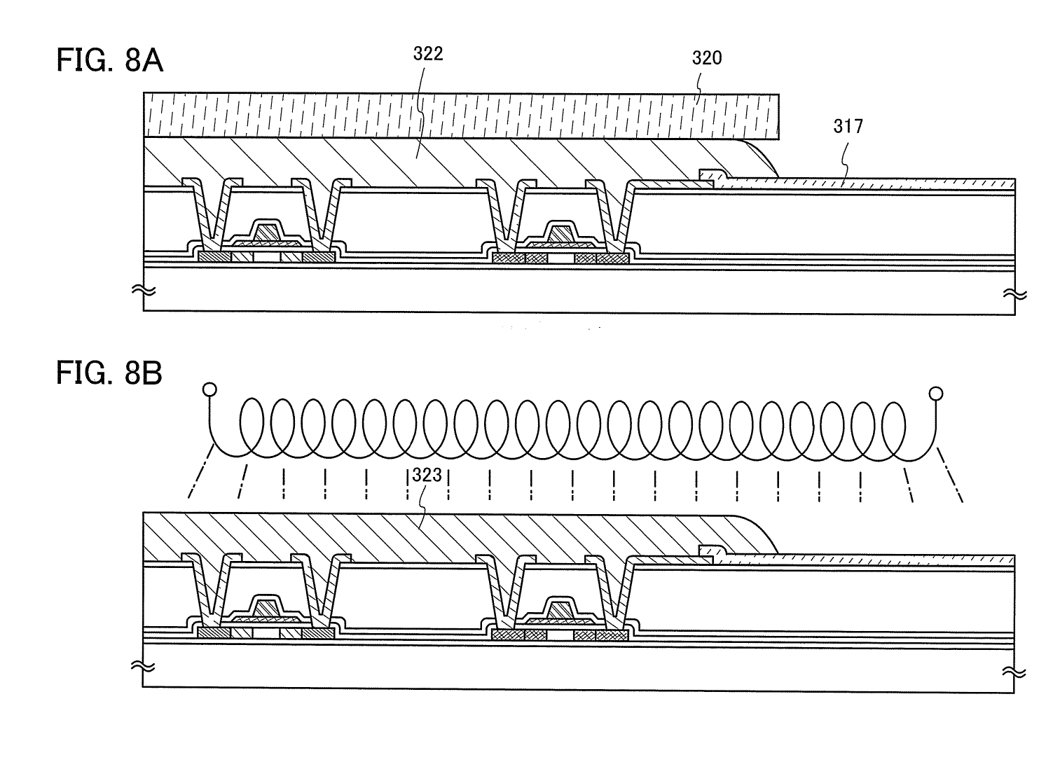

Next, as shown in FIG. 8A, an organic solvent is used as an etchant to perform wet etching of the thin film 321. As the organic solvent used as the etchant, medium alcohol in which the carbon number is in the range of 3 to 5, such as butanol or propanol is preferable. By using the above-described alcohol as an etchant, the etching rate suitable for etching and high selection ratio with respect to the mask 320 can be obtained when wet etching is performed on the thin film 321 which has been hardened by baking. Further, by using such an organic solvent as an etchant, unlike the case where an inorganic material such as hydrofluoric acid is used as an etchant, roughness of the surface of a conductive film such as a wiring, an electrode, or the like under the thin film 321 can be suppressed and the risk for handling can be reduced.

In this embodiment mode, 2-butanol is used as the etchant to perform wet etching. By the wet etching, a thin film 322 which has been processed (patterned) into a desired shape can be formed. By formation of the thin film 322, the anode 317 is partially exposed.

Next, the mask 320 is removed. As a stripper for removing the mask 320, the one which can selectively remove the mask 320 is used. For example, in the case where the mask 320 is formed of a novolac resin, a stripper containing 2-aminoethanol and glycol ether can be used.

Next, as shown in FIG. 8B, heat treatment called curing is performed on the thin film 322. Process temperature of curing is set to the temperature in the range enough to polymerize a siloxane-based material contained in the thin film 322 and/or promote vaporization of the organic solvent contained in the thin film 322. Specifically, the temperature of curing is set to be higher than the boiling point of the organic solvent contained in the suspension for forming the thin film 318.

In this embodiment mode, curing is performed at 300° C. to 350° C. for about 1 hour. Owing to this curing, the siloxane-based material in the thin film 322 is polymerized and/or the organic solvent contained in the thin film 322 further vaporizes than the case of baking, whereby an insulating film 323 of a siloxane resin having an opening through which the anode 317 is exposed is formed.

Next, in the present invention, before an electroluminescent layer 324 is formed, heat treatment in an atmospheric atmosphere or heat treatment in a vacuum atmosphere (vacuum baking) is performed to remove moisture, oxygen, or the like adsorbed in the insulating film 323 and the anode 317. Specifically, heat treatment is performed at a substrate temperature of 200° C. to 450° C., and preferably 250° C. to 300° C. for about 0.5 to 20 hours in a vacuum atmosphere. The pressure is preferably 4×10⁻⁵ Pa or less, and if possible, 4×10⁻⁶ Pa or less is the best. Further, in the case where the electroluminescent layer 324 is formed after heat treatment is performed in a vacuum atmosphere, the reliability can be further improved by putting the substrate in the vacuum atmosphere just before completion of formation of the electroluminescent layer 324. Further, the anode 317 may be irradiated with ultraviolet rays before or after the vacuum baking.

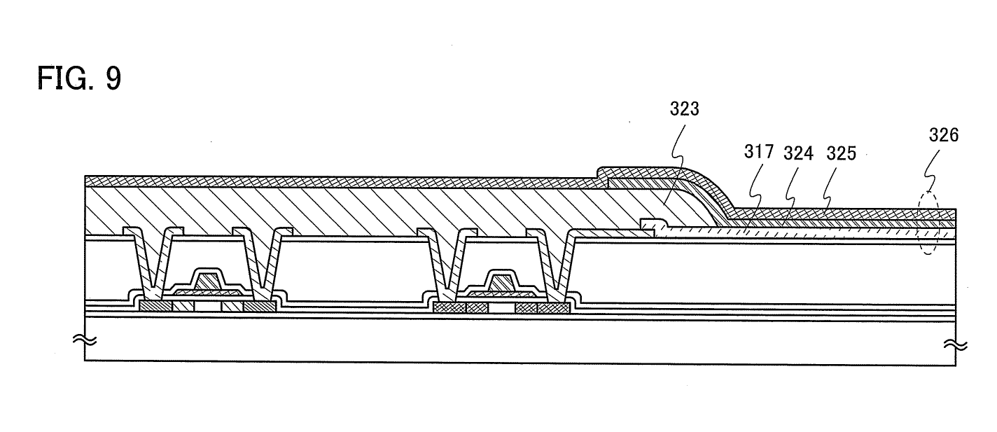

Next, as shown in FIG. 9, the electroluminescent layer 324 is formed over the anode 317. As for the electroluminescent layer 324, either a single layer or a plurality of layers is used, and not only an organic material but also an inorganic material may be contained in each layer. The luminescence of the electroluminescent layer 324 includes luminescence (fluorescence) upon returning to ground state from singlet-excited state and luminescence (phosphorescence) upon returning to ground state from triplet-excited state.

Next, a cathode 325 is formed to cover the electroluminescent layer 324. As the cathode 325, a metal, an alloy, an electrical conductive compound, a mixture thereof having a small work function, or the like can be typically used. Specifically, an alkali metal such as Li or Cs, an alkali earth metal such as Mg, Ca, or Sr, an alloy containing them (e.g., Mg:Ag or Al:Li), or a rare earth metal such as Yb or Er can be formed as well. Further, by formation of a layer containing a material having high electron injection properties so as to be in contact with the cathode 325, a normal conductive film formed of aluminum, an oxide conductive material, or the like can be used as well.

The anode 317, the electroluminescent layer 324, and the cathode 325 overlap with one another in an opening of the insulating film 323, and the overlapping portion corresponds to a light-emitting element 326.

Note that an insulating film may be formed over the cathode 325 after the formation of the light-emitting element 326. As the insulating film, similarly to the insulating film 311, a film through which a matter which causes increase of deterioration of a light-emitting element such as moisture or oxygen penetrates in lesser amount than those of other insulating films is used. Typically, a DLC film, a carbon nitride film, a silicon nitride film formed by an RF sputtering method, or the like is preferably used. Further, the above-described film through which a matter which causes increase of deterioration of a light-emitting element such as moisture or oxygen penetrates in lesser amount and a film through which the matter such as moisture or oxygen penetrates in more amount may be stacked to be used as the above-described insulating film as well.

Note that, although the structure in which light from the light-emitting element 326 is emitted to the substrate 300 side is shown in FIG. 9, the structure of a light-emitting element in which light is emitted to the side opposite to the substrate 300 side may be employed as well.

In practice, after the completion up to the one shown in FIG. 9, it is preferable to perform packaging (sealing) with a protective film (e.g., a bonding film or an ultraviolet-curable resin film) which gets less air circulation or a light-transmitting member for covering in order not to expose the one to the outside air. At that time, if the inside the member for covering is made an inert atmosphere or a hygroscopic material (e.g., barium oxide) is provided in the inside, reliability of the light-emitting element is improved.

Note that, although the case where the mask 320 is formed by a photolithography method is given as an example for description in this embodiment mode, the present invention is not limited to this structure. The mask 320 may be formed by a droplet discharging method, a printing method, or the like instead of the photolithography method as well.

Further, although the case where baking of a thin film is performed after the mask 320 is formed similarly to Embodiment Mode 1 is given as an example for description in this embodiment mode, the present invention is not limited to this structure. Like Embodiment Mode 2, baking of a thin film may be performed before the mask 320 is formed.

In the present invention, by the above-described manufacturing method, the taper angle in the edge of the insulating film 323 can be suppressed, that is, the gradient of the edge 207 can be suppressed. By the above-described structure, coverage of the electroluminescent layer 324 or the cathode formed later can be improved. With good coverage of the electroluminescent layer 324, short-circuiting between the anode 317 and the cathode in a hole formed in the electroluminescent layer 324 is prevented and occurrence of defects called shrink, that is, decrease in light-emitting area can be decreased, so that the reliability can be improved.

Further, according to the above-described method for manufacturing a semiconductor device, the problem in that hygroscopicity of the insulating film 323 is increased by increase of OH radicals does not occur unlike the case of dry etching. Therefore, the reliability of a light-emitting element and then the reliability of a semiconductor device can be prevented from being adversely affected by moisture in the insulating film. In addition, in the case of a semiconductor device having a light-emitting element, the deterioration of the light-emitting element can be suppressed by suppressing the hygroscopicity of an insulating film, whereby the reliability of the semiconductor device can be improved.

Furthermore, the insulating film 323 can be formed of a conventional non-photosensitive siloxane resin. Therefore, the manufacturing cost of the semiconductor device can be suppressed.

Furthermore, in the manufacturing method of this embodiment mode, baking for hardening a thin film can prevent the mask 320 from being fretted or solved by an organic solvent, that is, the baking for hardening a thin film also functions as heat treatment for improving the organic solvent resistance of the mask 320.

Further, although the insulating film 323 which functions as a bank of the light-emitting element 326 is formed by the manufacturing method of the present invention, the present invention is not limited to this structure. In the case where an insulating film other than the bank, for example, the insulating film 310 is formed of a siloxane resin, the insulating film 310 may be formed by the manufacturing method of the present invention. In this case, the gradient of the edge of each opening formed in the insulating film 310 can be suppressed. Therefore, extremely thinning or disconnecting due to a step of the conductive films 312 to 315 in the edge of each opening can be prevented.

This embodiment mode can be implemented combining with any of the above-described embodiment modes as appropriate.

### Embodiment Mode 4

Next, a specific method for manufacturing a semiconductor device of the present invention is described. Note that, although a transistor is shown as an example of a semiconductor element in this embodiment mode, a semiconductor element used in the semiconductor device of the present invention is not limited to this. For example, other than a transistor, a memory element, a diode, a resistor, a capacitor, an inductor, or the like can be used as well.

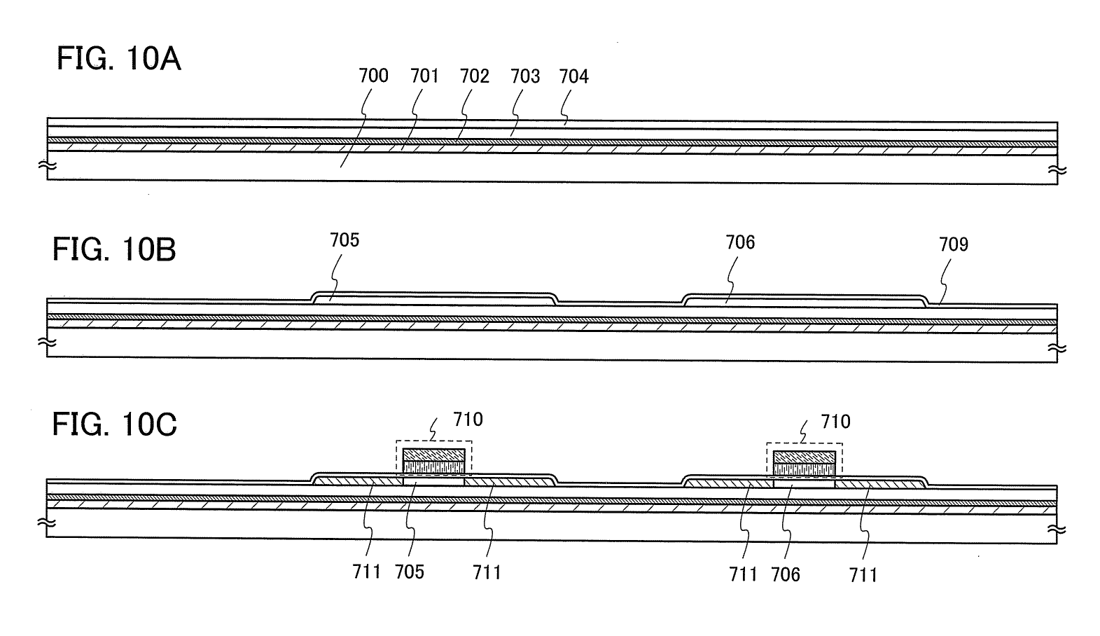

First, as shown in FIG. 10A, an insulating film 701, a separation layer 702, an insulating film 703, and a semiconductor film 704 are formed sequentially over a substrate 700 having heat-resisting properties. The insulating film 701, the separation layer 702, the insulating film 703, and the semiconductor film 704 can be formed consecutively.

As the substrate 700, for example, a glass substrate made of barium-borosilicate glass or alumino-borosilicate glass, a quartz substrate, a ceramic substrate, or the like can be used. Further, a metal substrate including a stainless-steel substrate or a semiconductor substrate such as a silicon substrate may be used as well. A substrate made of a synthetic resin having flexibility such as plastics which generally has the heat-resistance temperature which is lower than those of the above-described substrates can be used as long as it can withstand the process temperature in a manufacturing process.

As examples of a plastic substrate, the following can be given: polyester typified by polyethylene terephthalate (PET); polyethersulfone (PES); polyethylene naphthalate (PEN); polycarbonate (PC); nylon; polyetheretherketone (PEEK); polysulfone (PSF); polyetherimide (PEI); polyarylate (PAR); polybutylene terephthalate (PBT); polyimide; an acrylonitrile-butadiene-styrene resin; polyvinyl chloride; polypropylene; polyvinyl acetate; an acrylic resin; and the like.

Note that, although the separation layer 702 is provided over the entire surface of the substrate 700 in this embodiment mode, the present invention is not limited to this structure. For example, the separation layer 702 may be formed partially over the substrate 700 by a photolithography method or the like as well.

Each of the insulating films 701 and 703 is formed of an insulating material such as silicon oxide, silicon nitride (e.g., SiNₓ or Si₃N₄), silicon oxynitride (SiOₓN_{y} where x>y>0), or silicon nitride oxide (SiNₓO_{y} where x>y>0) by a CVD method, a sputtering method, or the like.

By provision of the insulating films 701 and 703, alkaline earth metal or alkali metal such as Na contained in the substrate 700 is prevented from being diffused into the semiconductor film 704 and adversely affecting the characteristics of a semiconductor element such as a transistor. In addition, the insulating film 703 functions to prevent an impurity element contained in the separation layer 702 from being diffused into the semiconductor film 704, and also functions to protect semiconductor elements in the later step of separating the semiconductor elements.

Each of the insulating films 701 and 703 is either a single layer of an insulating film or a stacked layer of a plurality of insulating films. In this embodiment mode, the insulating film 703 is formed by sequentially stacking a 100-nm-thick silicon oxynitride film, a 50-nm-thick silicon nitride oxide film, and a 100-nm-thick silicon oxynitride film. However, the material, thickness, and number of stacked layers of each of the insulating films are not limited to the above. For example, the silicon oxynitride film which is the bottom layer may be replaced with a siloxane resin film having a thickness of 0.5 to 3 μm that is formed by a spin-coating method, a slit-coating method, a droplet discharging method, a printing method, or the like. Further, the silicon nitride oxide film which is the middle layer may be replaced with a silicon nitride (e.g., SiNₓ or Si₃N₄) film. Further, the silicon oxynitride film which is the top layer may be replaced with a silicon oxide film. Further, the thickness of each film is preferably 0.05 to 3 μm, and can be freely selected in this range.

Alternatively, it is also possible that the bottom layer of the insulating film 703, which is the closest to the separation layer 702, be formed of a silicon oxynitride film or a silicon oxide film, the middle layer of the same be formed of a siloxane resin, and the top layer of the same be formed of a silicon oxide film.

The silicon oxide film can be formed by thermal CVD, plasma CVD, atmospheric pressure CVD, bias ECR-CVD, or the like, using a mixed gas of silane and oxygen, TEOS (tetraethoxysilane) and oxygen, or the like. The silicon nitride film can be typically formed by plasma CVD using a mixed gas of silane and ammonia. The silicon oxynitride film and the silicon nitride oxide film can be typically formed by plasma CVD using a mixed gas of silane and dinitrogen monoxide.

As the separation layer 702, a metal film, a metal oxide film, or a stacked film of a metal film and a metal oxide film can be used. The metal film and the metal oxide film employ either a single-layer structure or a stacked-layer structure of a plurality of layers. Further, other than a metal film and/or a metal oxide film, metal nitride and/or metal oxynitride can be used as well. The separation layer 702 can be formed by a sputtering method or a CVD method such as a plasma CVD method.

As examples of a metal used for the separation layer 702, the following can be given: tungsten (W), molybdenum (Mo), titanium (Ti), tantalum (Ta), niobium (Nb), nickel (Ni), cobalt (Co), zirconium (Zr), zinc (Zn), ruthenium (Ru), rhodium (Rh), palladium (Pd), osmium (Os), iridium (Ir), and the like. Other than such a film formed of the above-described metal, the separation layer 702 may also be formed of a film made of an alloy containing the above-described metal as a main component or a compound containing the above-described metal.

Further, the separation layer 702 may also be formed of a film made of simple substance silicon (Si) or a film made of a compound containing silicon (Si) as a main component. Alternatively, a film formed of an alloy of silicon (Si) and the above-described metal may be used. A film containing silicon can have any of amorphous, microcrystalline, and polycrystalline structures.

The separation layer 702 employs either a single-layer structure of the above-described film or a stacked-layer structure of the above-described plurality of films. The separation layer 702 having a stacked-layer structure of a metal film and a metal oxide film can be formed by forming a base metal film and then oxidizing or nitriding the surface of the metal film. Specifically, plasma treatment may be applied to the base metal film in an oxygen atmosphere or a dinitrogen monoxide atmosphere, or thermal treatment may be applied to the metal film in an oxygen atmosphere or a dinitrogen monoxide atmosphere. Further, oxidation of the metal film can be performed as well by formation of a silicon oxide film or a silicon oxynitride film on the base metal film. Similarly, nitridation of the metal film can be performed as well by formation of a silicon nitride oxide film or a silicon nitride film on the base metal film.

As the plasma treatment for oxidation or nitridation of the metal film, high-density plasma treatment in which the plasma density is 1×10¹¹ cm⁻³ or more, and preferably in the range of 1×10¹¹ cm⁻³ and 9×10¹⁵ cm⁻³ both inclusive, and a high frequency such as microwaves (e.g., a frequency of 2.45 GHz) is used may be performed.

Note that, although the separation layer 702 formed of a stack of a metal film and a metal oxide film may be formed by oxidizing the surface of a base metal film, it may also be formed by separate formation of a metal oxide film after formation of a metal film. For example, in the case of using tungsten as a metal, a tungsten film is formed as a base metal film by a sputtering method, a CVD method, or the like, and then plasma treatment is applied to the tungsten film. Accordingly, the tungsten film that is a metal film and a metal oxide film that is in contact with the metal film and is formed of oxide of tungsten can be formed.

Note that oxide of tungsten is expressed by WOₓ where x is in the range of 2 to 3 both inclusive. There are cases where x is 2 (WO₂), x is 2.5 (W₂O₅), x is 2.75 (W₄O₁₁), and x is 3 (WO₃). For formation of oxide of tungsten, there is no particular limitation on the value of x, and the value of x may be determined based on the etching rate or the like.

It is preferable that the semiconductor film 704 be formed after the formation of the insulating film 703 without exposure to air. The thickness of the semiconductor film 704 is 20 to 200 nm (preferably 40 to 170 nm, and more preferably 50 to 150 nm). Note that the semiconductor film 704 may be either an amorphous semiconductor or a polycrystalline semiconductor. Further, not only silicon but also silicon germanium can be used for the semiconductor. In the case of using silicon germanium, the concentration of germanium is preferably about 0.01 to 4.5 at. %.

Note that the semiconductor film 704 may be crystallized by a known technique. As known crystallization methods, there are a laser crystallization method using laser light and a crystallization method using a catalytic element. Further, it is also possible to combine the crystallization method using a catalytic element and the laser crystallization method. Further, in the case of using a substrate having high heat-resisting properties such as a quartz substrate as the substrate 700, any of the following can be used as well: a thermal crystallization method using an electrically-heated oven, a lamp annealing crystallization method using infrared light, a crystallization method using a catalytic element, and a crystallization method combining high temperature annealing at about 950° C.

For example, in the case of using laser crystallization, heat treatment at 550° C. for 4 hours is performed on the semiconductor film 704 before the laser crystallization in order to improve the resistance of the semiconductor film 704 to laser. Crystals with a large grain size can be obtained by using a continuous-wave solid-state laser and performing irradiation with the second to fourth harmonics of the fundamental wave. For example, typically, the second harmonic (532 nm) or the third harmonic (355 nm) of an Nd:YVO₄ laser (fundamental wave of 1064 nm) is preferably used. Specifically, laser light emitted from a continuous-wave YVO₄ laser is converted into a harmonic with a nonlinear optical element, so that laser light having an output of 10 W is obtained. Then, the laser light is preferably shaped into a rectangular shape or an elliptical shape with optics on the irradiation surface and then emitted to the semiconductor film 704. In this case, an energy density of about 0.01 to 100 MW/cm² (preferably, 0.1 to 10 MW/cm²) and a scanning rate of about 10 to 2000 cm/sec are needed.

As a continuous-wave gas laser, an Ar laser, a Kr laser, or the like can be used. As a continuous-wave solid-state laser, the following can be used: a YAG laser, a YVO₄ laser, a YLF laser, a YAlO₃ laser, a forsterite (Mg₂SiO₄) laser, a GdVO₄ laser, a Y₂O₃ laser, a glass laser, a ruby laser, an alexandrite laser, a Ti:sapphire laser, or the like.

Further, as a pulsed laser, the following can be used: an Ar laser, a Kr laser, an excimer laser, a CO₂ laser, a YAG laser, a Y₂O₃ laser, a YVO₄ laser, a YLF laser, a YAlO₃ laser, a glass laser, a ruby laser, an alexandrite laser, a Ti:sapphire laser, a copper vapor laser, or a gold vapor laser.

The repetition rate of pulsed laser light may be set to 10 MHz or more, so that laser crystallization can be performed with a repetition rate which is extremely higher than the normally used repetition rate in the range of several ten to several hundred Hz. It is said that it takes several ten to several hundred nsec for the semiconductor film 704 to be completely solidified after being irradiated with pulsed laser light. Therefore, by using laser light with the above-described repetition rate, the semiconductor film 704 can be irradiated with a laser pulse after it is melted by the previous laser light but before it becomes solidified. Accordingly, the solid-liquid interface in the semiconductor film 704 can be moved continuously and thus, the semiconductor film 704 having crystal grains that have grown in the scanning direction can be formed. Specifically, an aggregation of crystal grains having a width of about 10 to 30 μm in the scanning direction and a width of about 1 to 5 μm in the direction perpendicular to the scanning direction can be formed. By formation of crystal grains of single crystals that have continuously grown in the scanning direction, the semiconductor film 704 having few crystal-grain boundaries at least in the channel direction of a transistor can be formed.

Note that laser crystallization can be performed by irradiation with a fundamental wave of continuous-wave laser light and a harmonic of continuous-wave laser light in parallel, or alternatively, by irradiation with a fundamental wave of continuous-wave laser light and a harmonic of pulsed laser light in parallel.

Note that laser irradiation may be performed in an inert gas atmosphere such as a rare gas or a nitrogen gas. Accordingly, roughness of the semiconductor surface by laser irradiation can be suppressed, and variations in threshold voltage of TFTs resulting from variations in interface state density can be suppressed.

By the above-described laser irradiation, the semiconductor film 704 with improved crystallinity can be formed. Note that it is also possible to prepare and use a polycrystalline semiconductor formed by a sputtering method, a plasma CVD method, a thermal CVD method, or the like, as the semiconductor film 704.

Further, although the semiconductor film 704 is crystallized in this embodiment mode, it is not necessarily required to be crystallized and with the state of an amorphous silicon film or a microcrystalline semiconductor film, the following process may be started. A transistor using an amorphous semiconductor or a microcrystalline semiconductor is advantageous in low cost and high yield since the number of manufacturing steps is smaller than that of a transistor using a polycrystalline semiconductor.

An amorphous semiconductor can be obtained by decomposing a gas containing silicon by glow discharge. As examples of the gas containing silicon, SiH₄, Si₂H₆, and the like can be given. The gas containing silicon may be diluted with hydrogen or hydrogen and helium.

Next, channel doping is performed on the semiconductor film 704, by which an impurity element which provides p-type conductivity or an impurity element which provides n-type conductivity is added at a low concentration. The channel doping may be performed either to the whole of the semiconductor film 704 or to selectively part of the semiconductor film 704. As the impurity element which provides p-type conductivity, boron (B), aluminum (Al), gallium (Ga), or the like can be used. As the impurity element which provides n-type conductivity, phosphor (P), arsenic (As), or the like can be used. In this embodiment mode, boron (B) is used as the impurity element to be added so as to be contained at concentrations of 1×10¹⁶ to 5×10¹⁷/cm³.

Next, as shown in FIG. 10B, the semiconductor film 704 is processed (patterned) into a predetermined shape, so that island-shaped semiconductor films 705 and 706 are formed. Then, a gate insulating film 709 is formed so as to cover the island-shaped semiconductor films 705 and 706. The gate insulating film 709 can be formed of a single-layer structure or a stacked-layer structure of a film (films) containing silicon nitride, silicon oxide, silicon nitride oxide, and/or silicon oxynitride, by a plasma CVD method, a sputtering method, or the like. When the gate insulating film 709 is formed of a stacked-layer structure, it is preferable to form a three-layer structure in which a silicon oxide film, a silicon nitride film, and a silicon oxide film are stacked over the substrate 700.

The gate insulating film 709 may also be formed by oxidizing or nitriding the surfaces of the island-shaped semiconductor films 705 and 706 with high-density plasma treatment. The high-density plasma treatment is performed by using, for example, a mixed gas of a rare gas such as He, Ar, Kr, or Xe and oxygen, nitrogen oxide, ammonia, nitrogen, hydrogen, or the like. In this case, plasma with a low electron temperature and high density can be generated by exciting plasma with introduction of microwaves. By oxidizing or nitriding the surfaces of the semiconductor films with oxygen radicals (including OH radicals in some cases) or nitrogen radicals (including NH radicals in some cases) generated by such high-density plasma, an insulating film with a thickness of 1 to 20 nm, and typically 5 to 10 nm is formed to be in contact with the semiconductor films. Such a 5- to 10-nm-thick insulating film is used as the gate insulating film 709.

Oxidation or nitridation of the semiconductor films by the above-described high-density plasma treatment proceeds by solid-phase reaction. Therefore, interface state density between the gate insulating film and the semiconductor films can be suppressed to quite low. Further, by directly oxidizing or nitriding the semiconductor films with high-density plasma treatment, variations in thickness of the insulating film to be formed can be suppressed. Furthermore, in the case where the semiconductor films have crystallinity and the surfaces of the semiconductor films are oxidized by solid-phase reaction with high-density plasma treatment, fast speed of oxidation only in crystal grain boundaries can be prevented, so that a uniform gate insulating film in which the interface state density is low can be formed. By formation of a transistor whose gate insulating film partially or wholly includes an insulating film formed by high-density plasma treatment, variations in characteristics thereof can be suppressed.

Next, as shown in FIG. 10C, a conductive film is formed over the gate insulating film 709, and the conductive film is processed (patterned) into a predetermined shape, so that electrodes 710 are formed above the island-shaped semiconductor films 705 and 706. In this embodiment mode, each of the electrodes 710 is formed by patterning two stacked conductive films. For each conductive film, tantalum (Ta), tungsten (W), titanium (Ti), molybdenum (Mo), aluminum (Al), copper (Cu), chromium (Cr), niobium (Nb), or the like can be used. Further, an alloy containing the above-described metal as a main component or a compound containing the above-described metal may be used as well. Further alternatively, a semiconductor doped with an impurity element such as phosphorus which provides one conductivity type to a semiconductor film, such as polycrystalline silicon may be used.

In this embodiment mode, a tantalum nitride film or a tantalum (Ta) film is used as a first-layer conductive film, and a tungsten (W) film is used as a second-layer conductive film. In addition to the above-described example described in this embodiment mode, the following combination of two conductive films can be given as an example thereof: a tungsten nitride film and a tungsten film; a molybdenum nitride film and a molybdenum film; an aluminum film and a tantalum film; an aluminum film and a titanium film; or the like. Tungsten and tantalum nitride have high heat-resisting properties; therefore, after the formation of the two conductive films, heat treatment for the purpose of thermal activation can be performed. Further, as other examples of the combination of two conductive films, there are a combination of silicon doped with an impurity which provides n-type conductivity and nickel silicide, a combination of Si doped with an impurity which provides n-type conductivity and WSiₓ, and the like.

Further, although each of the electrodes 710 is formed of a stacked two conductive layers in this embodiment mode, this embodiment mode is not limited to this structure. Each gate electrode 710 may be formed of a single-layer conductive film or a stacked-layer structure including three or more conductive films. In the case of using a stacked-layer structure in which three or more conductive films are stacked, a stacked-layer structure of a molybdenum film, an aluminum film, and a molybdenum film is preferably adopted.

Each conductive film can be formed by a CVD method, a sputtering method, or the like. In this embodiment mode, the first-layer conductive film is formed to a thickness of 20 to 100 nm and the second-layer conductive film is formed to a thickness of 100 to 400 nm.

Note that, as a mask used for the formation of the electrodes 710, a mask made of silicon oxide, silicon oxynitride, or the like may be used instead of the resist mask. In this case, an additional step for formation of a mask of silicon oxide, silicon oxynitride, or the like by patterning is needed but the electrodes 710 having desired widths can be formed since the film thickness reduction of a mask thereof at the time of etching is smaller than that of a resist. Further, the electrodes 710 can also be formed selectively by a droplet discharging method without using a mask.

Next, the island-shaped semiconductor films 705 and 706 are doped with an impurity element which provides n-type conductivity (typically, P (phosphorus) or As (arsenic)) with the electrodes 710 as masks at a low concentration (a first doping step). The conditions of the first doping step are as follows: the dosage is 1×10¹⁵ to 1×10¹⁹/cm³ and the acceleration voltage is 50 to 70 keV. However, the present invention is not limited to them. By this first doping step, doping is performed through the gate insulating film 709, so that low concentration impurity regions 711 are formed in each of the island-shaped semiconductor films 705 and 706. Note that the first doping step may be performed while covering the island-shaped semiconductor film 706, which is to be a p-channel transistor, with a mask.

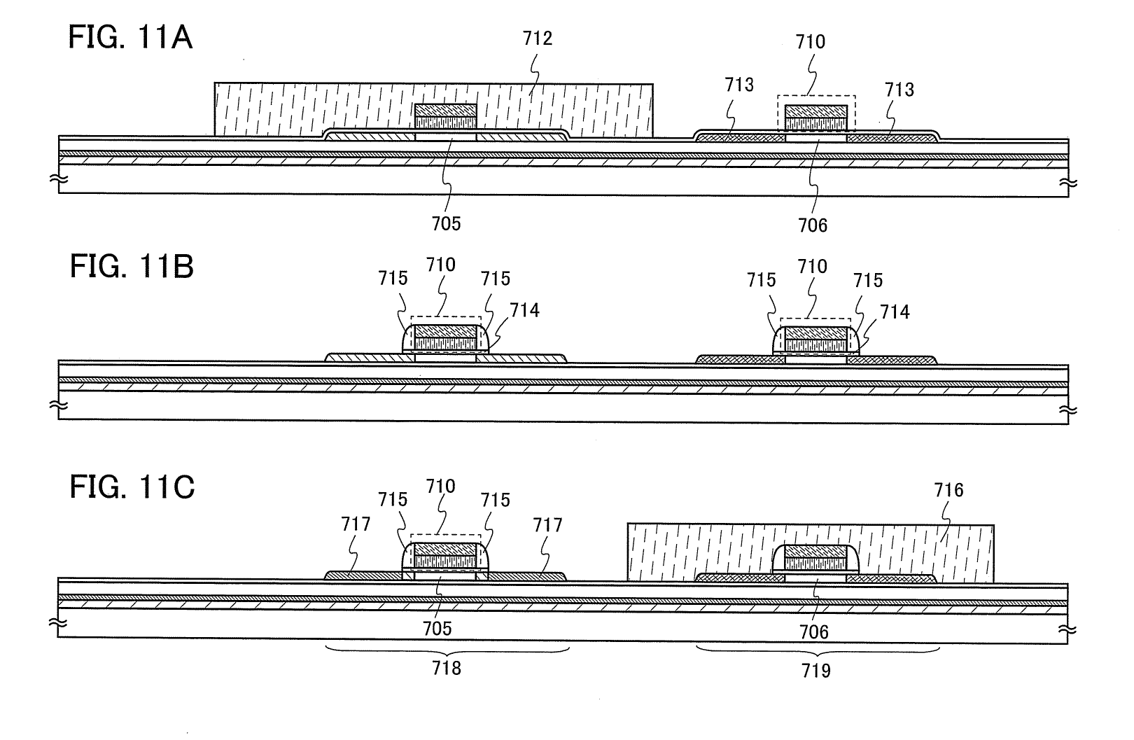

Next, as shown in FIG. 11A, a mask 712 is formed so as to cover the island-shaped semiconductor film 705 that is to be included in an n-channel transistor. Then, the island-shaped semiconductor film 706 is doped with an impurity element which provides p-type conductivity (typically B (boron)) with the mask 712 and the electrode 710 as masks at a high concentration (a second doping step). The conditions of the second doping step are as follows: the dosage is 1×10¹⁹ to 1×10²⁰/cm³ and the acceleration voltage is 20 to 40 keV. By this second doping step, doping is performed through the gate insulating film 709, so that p-type high concentration impurity regions 713 are formed in the island-shaped semiconductor film 706.

Next, as shown in FIG. 11B, the mask 712 is removed by ashing or the like, and then an insulating film is formed so as to cover the gate insulating film 709 and the electrodes 710. The insulating film is formed of a single-layer structure or a stacked-layer structure of a silicon film, a silicon oxide film, a silicon oxynitride film, a silicon nitride oxide film, and/or a film containing an organic material such as an organic resin, by a plasma CVD method, a sputtering method, or the like. In this embodiment mode, a 100-nm-thick silicon oxide film is formed by a plasma CVD method.

Next, the insulating film and the gate insulating film 709 are partially etched by anisotropic etching mainly in the perpendicular direction. By this anisotropic etching, the gate insulating film 709 is partially etched to leave gate insulating films 714 that are partially formed over the island-shaped semiconductor films 705 and 706. Further, the insulating film formed so as to cover the gate insulating film 709 and the electrodes 710 is etched partially by the anisotropic etching, so that sidewalls 715 being in contact with the side surfaces of the electrodes 710 are formed. The sidewalls 715 are used as doping masks for formation of LDD (lightly doped drain) regions. In this embodiment mode, a mixed gas of CHF₃ and He is used as an etching gas. Note that the process for forming the sidewalls 715 is not limited to this.

Next, as shown in FIG. 11C, a mask 716 is formed so as to cover the island-shaped semiconductor film 706 that is to be included in a p-channel transistor. Then, the island-shaped semiconductor film 705 is doped with an impurity element which provides n-type conductivity (typically, P or As) with the mask 716, the electrode 710, and the sidewall 715 as masks at a high concentration (a third doping step). The conditions of the third doping step are as follows: the dosage is 1×10¹⁹ to 1×10²⁰/cm³ and the acceleration voltage is 60 to 100 keV. By this third doping step, n-type high concentration impurity regions 717 are formed in the island-shaped semiconductor film 705.

Note that the sidewalls 715 function as masks later at the time of forming low concentration impurity regions or non-doped offset regions below the sidewalls 715 by doping the semiconductor films with an impurity which provides n-type conductivity at a high concentration. Therefore, in order to control each of the width of the low concentration impurity regions or the non-doped offset regions, the size of the sidewalls 715 may be controlled by the anisotropic etching conditions for the formation of the sidewalls 715 or the thickness of the insulating film for the formation of the sidewalls 715 being changed as appropriate. Note that, in the semiconductor film 706, low concentration impurity regions or non-doped offset regions may be formed below the sidewalls 715.

Next, the mask 716 is removed by ashing or the like, and then the impurity regions may be activated by heat treatment. For example, a 50-nm-thick silicon oxynitride film may be formed, and then followed by heat treatment at 550° C. for 4 hours in a nitrogen atmosphere.

Alternatively, a silicon nitride film containing hydrogen may be formed to a thickness of 100 nm, and may be followed by a step for hydrogenising the island-shaped semiconductor films 705 and 706 with heat treatment at 410° C. for 1 hour in a nitrogen atmosphere. Alternatively, a step for hydrogenising the island-shaped semiconductor films 705 and 706 with heat treatment at 300° C. to 450° C. for 1 hour to 12 hours in an atmosphere containing hydrogen may be performed. As the heat treatment, a thermal annealing method, a laser annealing method, an RTA method, or the like can be used. By the heat treatment, not only hydrogenation but also activation of the impurity elements that has been added into the semiconductor films can be performed. Further, as another alternative method for hydrogenation, plasma hydrogenation (using plasma-excited hydrogen) may be performed. By such a hydrogenation step, dangling bonds can be terminated with thermally excited hydrogen.

Through the above-described series of steps, an n-channel transistor 718 and a p-channel transistor 719 are formed.

Note that, although a thin film transistor is given as an example for description in this embodiment mode, the present invention is not limited to this structure. Other than a thin film transistor, a transistor formed using single-crystalline silicon, a transistor formed using an SOI, or the like can be used as well. Further, a transistor using an organic semiconductor or a transistor using a carbon nanotube may be used as well.

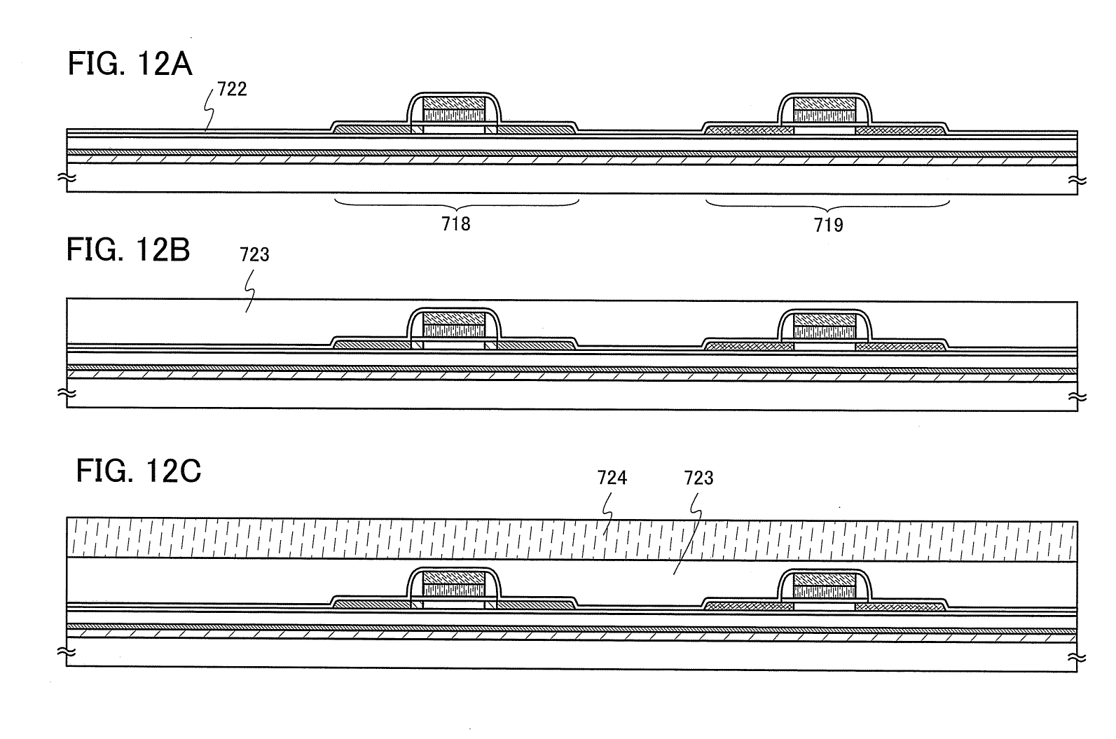

Next, as shown in FIG. 12A, an insulating film 722 for protection of the transistors 718 and 719 is formed. Although the insulating film 722 is not necessarily provided, provision of the insulating film 722 can prevent penetration of an impurity such as an alkali metal or an alkaline earth metal into the transistors 718 and 719. Specifically, it is preferable to use silicon nitride, silicon nitride oxide, silicon oxynitride, aluminum nitride, aluminum oxide, silicon oxide, or the like as the insulating film 722. In this embodiment mode, an about-600-nm-thick silicon oxynitride film is used as the insulating film 722. In this case, the above-described hydrogenation step may be performed after formation of the silicon oxynitride film.

Then a thin film 723 containing a siloxane resin or a siloxane-based material which is a precursor of a siloxane resin is formed over the insulating film 722 to cover the transistors 718 and 719. The thin film 723 can be formed by application of a suspension into which a siloxane resin or a siloxane-based material is dispersed over the insulating film 722 to cover the transistors 718 and 719.

A solvent of the suspension is preferably an organic solvent into which a siloxane resin or a siloxane-based material can be dispersed; for example, propylene glycol monomethyl ether acetate (PGMEA), 3-methoxy-3-methyl-1-butanol (MMB), N-methyl-2-pyrrolidone (NMP), or the like can be used. In this embodiment mode, propylene glycolmonomethyl ether acetate (PGMEA) and 3-methoxy-3-methyl-1-butanol (MMB) are used. The application of a suspension can be performed by a spin-coating method in which the suspension is dropped on the insulating film 722 and then the substrate 700 is rapidly spun. Further, other than the spin-coating method, a slit-coating method, a dip-coating method, or the like may be used as well to perform the application of a suspension.

Next, heat treatment called prebaking is performed on the thin film 723 to harden the thin film 723. In this embodiment mode, by performing the prebaking, working property in a process after a mask is formed by a photolithography method can be improved. It is preferable that the temperature of prebaking be as high as the thin film 723 can be hardened for good workability but lower than the boiling point of the organic solvent in the thin film 723. In this embodiment mode, prebaking is performed at 90° C. to 100° C. for 30 seconds to 60 seconds.

Next, the thin film 723 is exposed to liquid developer to improve the adhesion between the thin film 723 and a resist. Then, as shown in FIG. 12C, a resist layer 724 is formed on the thin film 723 by using a resist. In this embodiment mode, a novolac resin is used as the resist. Then, heat treatment (prebaking of resist) at 110° C. to 120° C. for 30 seconds to 90 seconds is performed on the resist layer 724. With the above-described heat treatment, a less soluble layer is formed in the surface to harden the resist layer 724, whereby working property can be improved.

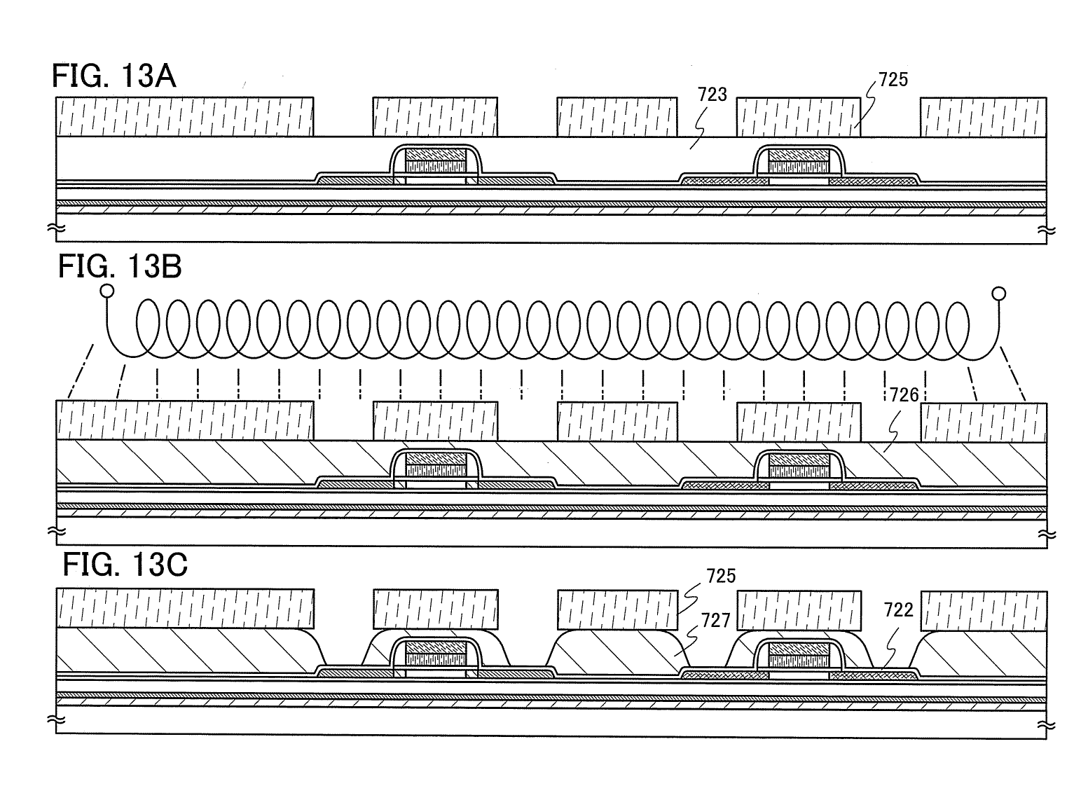

Next, the resist layer 724 is exposed to light and developed to remove part of the resist layer 724. Accordingly, as shown in FIG. 13A, a mask 725 provided selectively over the thin film 723 is formed.

Then, as shown in FIG. 13B, heat treatment called baking is performed to further harden the thin film 723. In FIG. 13B, the thin film 723 after being subjected to the baking is shown as a thin film 726. Temperature of baking is set to the temperature in the range enough to harden the thin film 723 as much as selective wet etching can be performed. Specifically, the temperature is set to be as high as a desired etching rate can be provided but lower than the boiling point of the organic solvent contained in the suspension for forming the thin film 723. In this embodiment mode, baking is performed at 130° C. to 140° C. for 0.5 hours to 1 hour.

Owing to baking, the mask 725 can be prevented from being fretted or solved by the organic solvent used in later wet etching.

Next, as shown in FIG. 13C, an organic solvent is used as an etchant to perform wet etching of the thin film 726. As the organic solvent used as the etchant, medium alcohol in which the carbon number is in the range of 3 to 5, such as butanol or propanol is preferable. By using the above-described alcohol as an etchant, the etching rate suitable for etching and high selection ratio with respect to the mask 725 can be obtained when wet etching is performed on the thin film 726 which has been hardened by baking. Further, by using such an organic solvent as an etchant, unlike the case where an inorganic material such as hydrofluoric acid is used as an etchant, roughness of the surface of a conductive film such as a wiring, an electrode, or the like under the thin film 726 can be suppressed and the risk for handling can be reduced.

In this embodiment mode, 2-butanol is used as the etchant to perform wet etching. By the wet etching, a thin film 727 which has been processed (patterned) into a desired shape can be formed. By formation of the thin film 727, the insulating film 722 is partially exposed.

Next, the mask 725 is removed. As a stripper for removing the mask 725, the one which can selectively remove the mask 725 is used. For example, in the case where the mask 725 is formed of a novolac resin, a stripper containing 2-aminoethanol and glycol ether can be used.

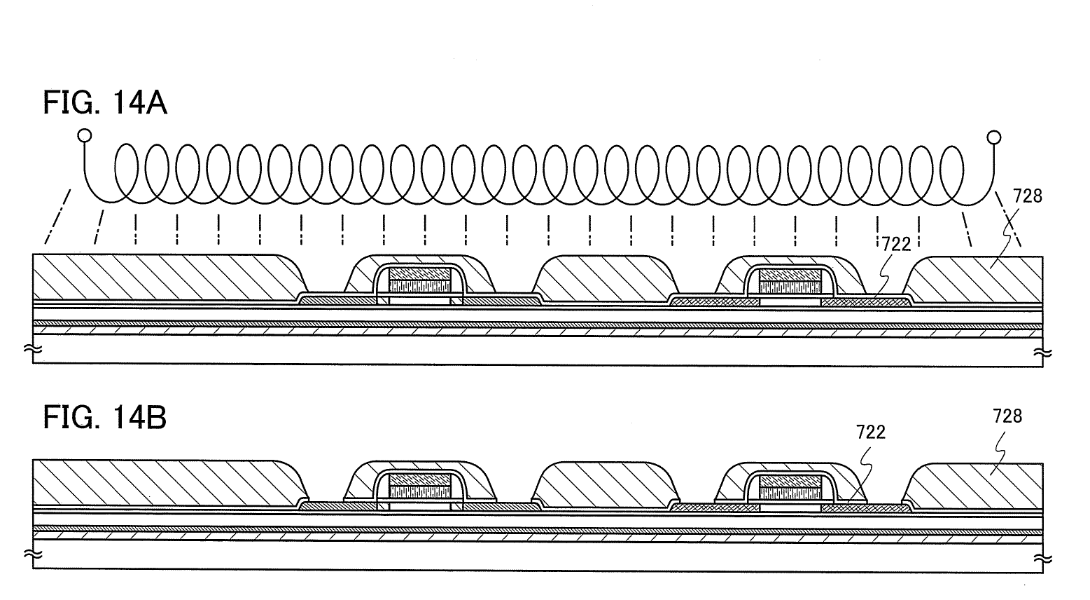

Next, as shown in FIG. 14A, heat treatment called curing is performed on the thin film 727. Process temperature of curing is set to the temperature in the range enough to polymerize a siloxane-based material contained in the thin film 727 and/or promote vaporization of the organic solvent contained in the thin film 727. Specifically, the temperature of curing is set to be higher than the boiling point of the organic solvent contained in the suspension for forming the thin film 723.

In this embodiment mode, curing is performed at 300° C. to 350° C. for about 1 hour. Owing to this curing, the siloxane-based material in the thin film 727 is polymerized and/or the organic solvent contained in the thin film 727 further vaporizes than the case of baking, whereby an insulating film 728 of a siloxane resin having an opening through which the insulating film 722 is exposed is formed.

Next, as shown in FIG. 14B, openings are formed in the insulating film 722 in the openings of the insulating film 728 through which parts of the island-shaped semiconductor films 705 and 706 are exposed. In this embodiment mode, the openings are formed by performing dry etching to the insulating film 722. When the openings are formed in the insulating film 722, the insulating film 728 is covered with a mask. A mixed gas of CHF₃ and He can be used as a gas used for dry etching; however, the present invention is not limited to this.

Note that the above-described dry etching step is not needed in the case where the insulating film 722 is not provided.

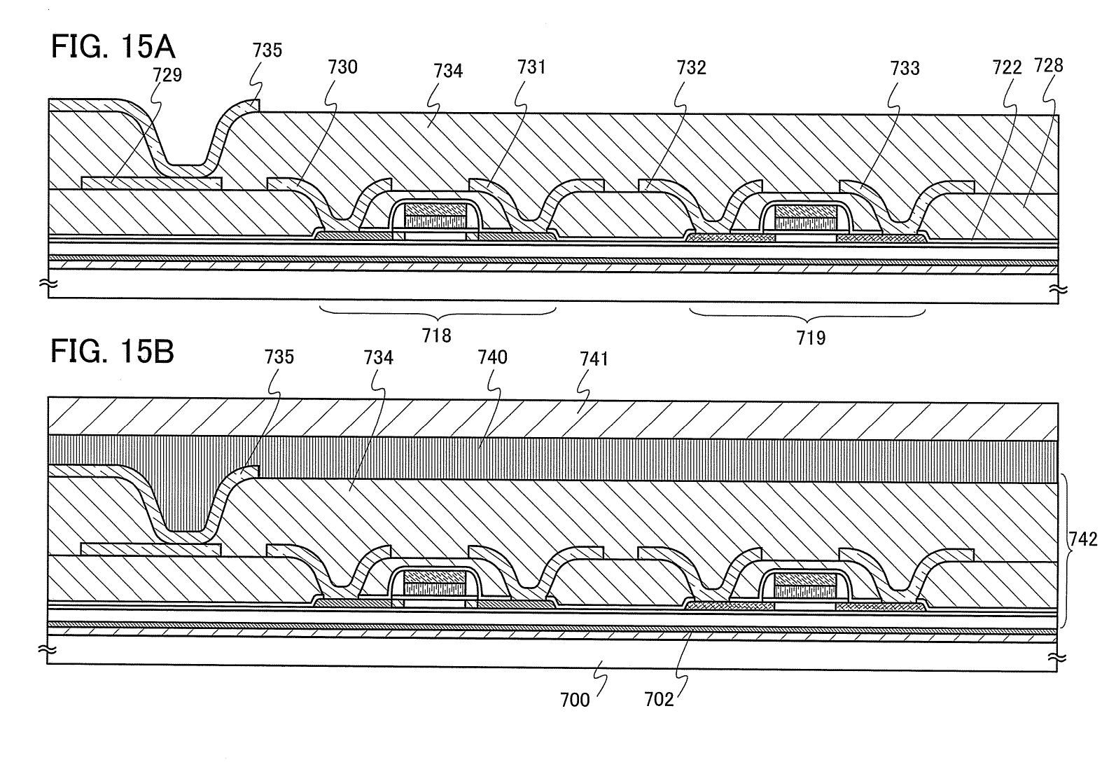

Then, as shown in FIG. 15A, a conductive film 729 and conductive films 730 and 731 which are in contact with the island-shaped semiconductor film 705 and conductive films 732 and 733 which are in contact with the island-shaped semiconductor film 706 are formed in the openings in the insulating films 722 and 728.

The conductive films 729 to 733 can be formed by a CVD method, a sputtering method, or the like. Specifically, each of the conductive films 729 to 733 can be formed of aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), silicon (Si), or the like. Alternatively, an alloy containing the above-described metal as a main component or a compound containing the above-described metal can be used as well. Each of the conductive films 729 to 733 can be formed of either a single layer of the above-described metal film or a plurality of stacked layers thereof.

As an example of an alloy containing aluminum as a main component, an alloy which contains aluminum as a main component and nickel can be given. Further, an alloy which contains aluminum as a main component, nickel, and at least one of carbon and silicon can also be given as an example of the same. Aluminum and aluminum silicon which have a low resistance value and are inexpensive are the most suitable materials for formation of the conductive films 729 to 733. In particular, when an aluminum silicon film is used, generation of hillocks in resist baking can be suppressed more than the case of using an aluminum film, at the time of patterning the conductive films 729 to 733. Further, instead of silicon (Si), Cu may be mixed into an aluminum film at about 0.5 wt. %.

Each of the conductive films 729 to 733 is preferably formed to have a stacked-layer structure of, for example, a barrier film, an aluminum silicon film, and a barrier film, or a stacked-layer structure of a barrier film, an aluminum silicon film, a titanium nitride film, and a barrier film. Note that the barrier film is, for example, a film formed of titanium, titanium nitride, molybdenum, molybdenum nitride, or the like. When barrier films are formed to sandwich an aluminum silicon film therebetween, generation of hillocks of aluminum or aluminum silicon can be further prevented. Further, in the case where a barrier film is formed of titanium which is a high reducible element, even when thin oxide films exist on the island-shaped semiconductor films 705 and 706, the oxide films can be reduced by titanium contained in the barrier film, whereby a favorable contact between the conductive films 730 to 733 and the island-shaped semiconductor films 705 and 706 can be obtained. Further, it is also possible to stack a plurality of barrier films. In this case, each of the conductive films 729 to 733 can have a five-layer structure in which titanium, titanium nitride, aluminum silicon, titanium, and titanium nitride are sequentially stacked.

Note that the conductive films 730 and 731 are connected to the high concentration impurity regions 717 of the n-channel transistor 718. The conductive films 732 and 733 are connected to the high concentration impurity regions 713 of the p-channel transistor 719.

Next, an insulating film 734 is formed so as to cover the conductive films 729 to 733. Then, an opening is formed in the insulating film 734 so as to partially expose the conductive film 729. Then, a conductive film 735 is formed so as to be in contact with the conductive film 729 in the opening. Any material that can be used for the conductive films 729 to 733 can be used as the material of the conductive film 735.

The insulating film 734 can be formed of an organic resin film, an inorganic insulating film, or a siloxane-based insulating film. As examples for an organic resin film, acrylic, epoxy, polyimide, polyamide, polyvinyl phenol, benzocyclobutene, and the like can be given. As examples for an inorganic insulating film, silicon oxide, silicon oxynitride, silicon nitride oxide, a film containing carbon typified by DLC (diamond-like carbon), and the like can be given. Note that a mask used for formation of an opening by a photolithography method can be formed by a droplet discharging method or a printing method. Further, the insulating film 734 can be formed by a CVD method, a sputtering method, a droplet discharging method, a printing method, or the like selected as appropriate depending on the material.

Note that the formation of the insulating film 734 may also employ the manufacturing method of the present invention. In this case, the manufacturing method of the insulating film 728 described referring to FIGS. 12B and 12C, 13A to 13C, and 14A can be used.

Next, as shown in FIG. 15B, a protective layer 740 is formed over the insulating film 734 so as to cover the conductive film 735. The protective layer 740 is formed of a material by which the insulating film 734 and the conductive film 735 can be protected at the time of separating the substrate 700 with the separation layer 702 used as a boundary later. For example, the protective layer 740 can be formed by applying an epoxy-based, acrylate-based, or silicone-based resin that is soluble in water or alcohols over the entire surface.

In this embodiment mode, the protective layer 740 is formed as follows: a water-soluble resin (VL-WSHL10, product of Toagosei Co., Ltd.) is applied to a thickness of 30 μm by a spin coating method; the resin is pre-cured by light exposure for 2 minutes; and the resin is cured completely by light exposure for 12.5 minutes in total (for 2.5 minutes from the rear surface and 10 minutes from the front surface). In the case of stacking a plurality of organic resins, part of the organic resins might be melted or adhesion thereof might become extremely high during an application step or a baking step depending on a solvent. Therefore, in the case where organic resins that are soluble in the same solvent are used for the insulating film 734 and the protective layer 740, it is preferable to form an inorganic insulating film (e.g., a silicon nitride film, a silicon nitride oxide film, an AlNₓ film, or an AlNₓO_{y} film) so as to cover the insulating film 734 in order that the protective layer 740 can be smoothly removed in a later step.

Next, layers from the insulating film 703 to the conductive film 735 formed over the insulating film 734 both inclusive, which include semiconductor elements typified by transistors and various conductive films, (hereinafter referred to as an “element formation layer 742”), and the protective layer 740 are separated from the substrate 700. In this embodiment mode, a first sheet member 741 is attached to the protective layer 740, and the element formation layer 742 and the protective layer 740 are separated from the substrate 700 by physical force. The separation layer 702 may partially remain without being entirely removed.

Further, the above-described separation may be performed by a method using etching of the separation layer 702. In this case, a trench is formed so as to partially expose the separation layer 702. The trench is formed by dicing, scribing, laser light (including UV light) processing, a photolithography method, or the like. The trench is needed to be deep enough to expose the separation layer 702. Then, halogen fluoride is used as an etching gas, and the gas is introduced through the trench. In this embodiment mode, etching is performed in which, for example, ClF₃ (chlorine trifluoride) is used, the temperature is 350° C., the flow rate is 300 sccm, the atmospheric pressure is 800 Pa, and the period of time is 3 hours. Further, nitrogen may be mixed into the ClF₃ gas. Using halogen fluoride such as ClF₃ enables the separation layer 702 to be selectively etched, so that the substrate 700 can be separated from the element formation layer 742. Note that halogen fluoride may be either gas or liquid.

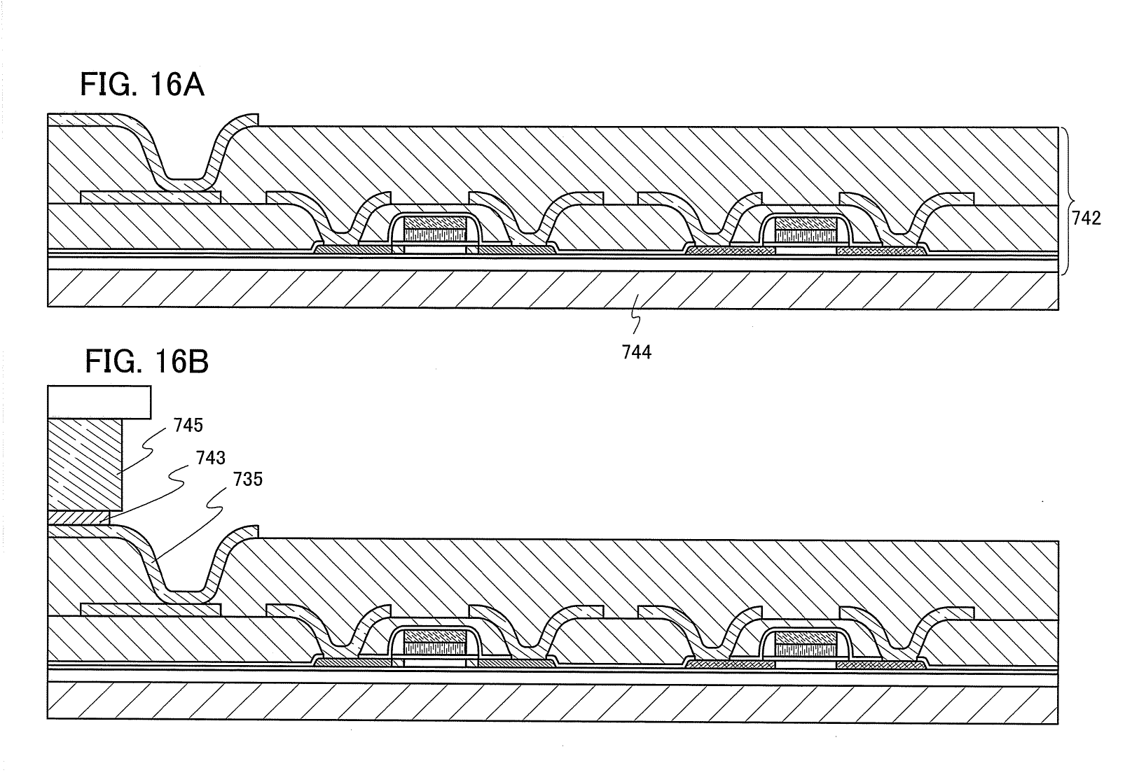

Next, as shown in FIG. 16A, a second sheet member 744 is attached to a surface of the element formation layer 742 that has been exposed by the above-described separation, the element formation layer 742 and the protective layer 740 are separated from the first sheet member 741, and then the protective layer 740 is removed.

As the second sheet member 744, an organic material such as a glass substrate made of barium-borosilicate glass, alumino-borosilicate glass, or the like, or flexible paper or plastic can be used. Further, as the second sheet member 744, a flexible inorganic material may be used as well. As a plastic substrate, ARTON (product of JSR Corporation) made of polynorbornene containing a polar group can be used. Further, the following can be used as well: polyester typified by polyethylene terephthalate (PET); polyethersulfone (PES); polyethylene naphthalate (PEN); polycarbonate (PC); nylon; polyetheretherketone (PEEK); polysulfone (PSF); polyetherimide (PEI); polyarylate (PAR); polybutylene terephthalate (PBT); polyimide; an acrylonitrile-butadiene-styrene resin; polyvinyl chloride; polypropylene; polyvinyl acetate; an acrylic resin; or the like.

Note that, in the case where semiconductor elements corresponding to a plurality of semiconductor devices are formed over the substrate 700, the element formation layer 742 is cut for each of the semiconductor devices. Cutting can be performed with a laser irradiation apparatus, a dicing apparatus, a scribing apparatus, or the like.

Next, as shown in FIG. 16B, an antenna 745 is electrically connected to the conductive film 735. Electrical connection between the antenna 745 and the conductive film 735 can be performed by pressure bonding with an anisotropic conductive film (ACF) 743. Other than the anisotropic conductive film, an anisotropic conductive paste (ACP) or the like may be used for the pressure bonding. Further, connection may also be performed with a conductive adhesive such as a silver paste, a copper paste, or a carbon paste, soldering, or the like.

Note that, although the example in which the antenna 745 which is separately prepared is electrically connected to the semiconductor elements after the formation of the semiconductor elements is described in this embodiment mode, the present invention is not limited to this structure. An antenna may be formed over the same substrate as the semiconductor elements. In this case, a conductive film which functions as an antenna may be formed such that part of the conductive film is in contact with the conductive film 735. The conductive film which functions as an antenna can be formed of a metal such as silver (Ag), gold (Au), copper (Cu), palladium (Pd), chromium (Cr), platinum (Pt), molybdenum (Mo), titanium (Ti), tantalum (Ta), tungsten (W), aluminum (Al), iron (Fe), cobalt (Co), zinc (Zn), tin (Sn), or nickel (Ni). The conductive film which functions as an antenna can also be formed of a film made of an alloy containing the above-described metal as a main component or a compound containing the above-described metal as well as the film formed of the above-described metal. The conductive film which functions as an antenna can be formed of either a single layer of the above-described film or a plurality of stacked layers thereof.

The conductive film which functions as an antenna can be formed by a CVD method, a sputtering method, a printing method such as screen printing or gravure printing, a droplet discharging method, a dispensing method, a plating method, a photolithography method, an evaporation method, or the like.

In the case of using a screen printing method, the conductive film which functions as an antenna can be formed by selectively printing a conductive paste in which conductive particles with a particle size of several nm to several ten μm are dispersed in an organic resin onto the insulating film 734. The conductive particles can be formed of silver (Ag), gold (Au), copper (Cu), nickel (Ni), platinum (Pt), palladium (Pd), tantalum (Ta), molybdenum (Mo), tin (Sn), lead (Pb), zinc (Zn), chromium (Cr), titanium (Ti), or the like. As well as such a metal, the conductive particles can also be formed of an alloy containing the above-described metal as a main component or a compound containing the above-described metal. Further, fine particles of silver halide or dispersible nanoparticles can be used as well. Further, as the organic resin contained in the conductive paste, polyimide, a siloxane-based resin, an epoxy resin, a silicone resin, or the like can be used.

As examples of an alloy of the above-described metals, the following combinations can be given: silver (Ag) and palladium (Pd), silver (Ag) and platinum (Pt), gold (Au) and platinum (Pt), gold (Au) and palladium (Pd), and silver (Ag) and copper (Cu). Further, conductive particles of copper (Cu) coated with silver (Ag) can be used as well, for example.

Note that the conductive film which functions as an antenna is preferably formed as follows: a conductive paste is applied by a printing method or a droplet discharging method, and then baked. For example, in the case of using conductive particles (e.g., particle size of 1 nm or more and 100 nm or less) containing silver as a main component as the conductive paste, the conductive film which functions as an antenna can be formed by baking the conductive paste at temperatures of 150° C. to 300° C. Baking may be performed either by lamp annealing with an infrared lamp, a xenon lamp, a halogen lamp, or the like, or by furnace annealing with an electric furnace. Further, laser annealing with an excimer laser or an Nd:YAG laser may be used as well. Further, fine particles containing solder or lead-free solder as a main component may be used as well; in that case, it is preferable to use fine particles with a particle size of 20 μm or less. Solder and lead-free solder have the advantage of low cost.

Note that, although the example of the semiconductor device in which the element formation layer 742 is separated from the substrate 700 is described in this embodiment mode, the above-described element formation layer 742 may be formed over the substrate 700 without providing the separation layer 702.

Further, although the manufacturing method of the semiconductor device including an antenna is described in this embodiment mode, the present invention is not limited to this structure. A semiconductor device manufactured by the manufacturing method of the present invention does not necessarily include an antenna.

Note that, although the case where the mask 725 is formed by a photolithography method is given as an example for description in this embodiment mode, the present invention is not limited to this structure. The mask 725 may be formed by a droplet discharging method, a printing method, or the like instead of the photolithography method as well.

Further, although the case where baking of a thin film is performed after the mask 725 is formed similarly to Embodiment Mode 1 is given as an example for description in this embodiment mode, the present invention is not limited to this structure. Like Embodiment Mode 2, baking of a thin film may be performed before the mask 725 is formed.

In this embodiment mode, the gradient of the edge of each opening formed in the insulating film 728 can be suppressed. Therefore, extremely thinning or disconnecting due to a step of the conductive films 730 to 733 in the edge of each opening can be prevented. Accordingly, the reliability of a semiconductor device can be improved.

Further, although the insulating film 728 is formed by the manufacturing method of the present invention, the present invention is not limited to this structure. Both of the insulating film 728 and the insulating film 734 may be formed by the manufacturing method of the present invention, or only the insulating film 734 out of the insulating film 728 and the insulating film 734 may be formed by the manufacturing method of the present invention. By formation of the insulating film 734 by the manufacturing method of the present invention, extremely thinning or disconnecting due to a step of the conductive film 735 in the edge of the opening can be prevented.

Further, according to the above-described manufacturing method of a semiconductor device, the problem in that hygroscopicity of the insulating film 728 is increased by increase of OH radicals does not occur unlike the case of dry etching. Therefore, the reliability of a semiconductor element such as the transistor 718, the transistor 719, or the like and the reliability of a semiconductor device can be prevented from being adversely affected by moisture in the insulating film 728.

Furthermore, the insulating film 728 can be formed of a conventional non-photosensitive siloxane resin. Therefore, the manufacturing cost of a semiconductor device can be suppressed.

Furthermore, in the manufacturing method of this embodiment mode, baking for hardening a thin film can prevent the mask 725 from being fretted or solved by an organic solvent, that is, the baking for hardening a thin film also functions as heat treatment for improving the organic solvent resistance of the mask 725.

This embodiment mode can be implemented combining with any of the above-described embodiment modes as appropriate.

### Embodiment 1

In this embodiment, a manufacturing method of the present invention, in which an insulating film is formed over a semiconductor element formed using a single crystalline substrate is described. Note that, although the case of using a transistor as a semiconductor element is given as an example for description in this embodiment, a semiconductor element formed using a single crystalline substrate is not limited to a transistor.

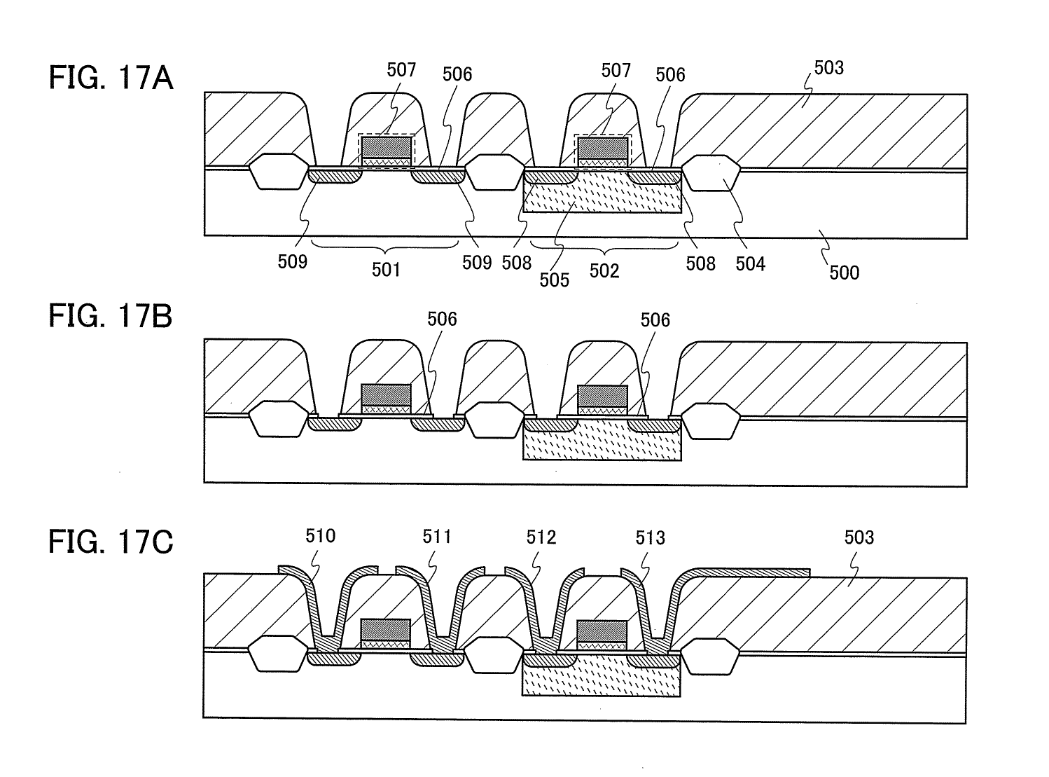

First, as shown in FIG. 17A, an insulating film 503 is formed so as to cover transistors 501 and 502 formed using a semiconductor substrate 500.

As the semiconductor substrate 500, a single crystalline silicon substrate having n-type or p-type conductivity or a compound semiconductor substrate (e.g., a GaAs substrate, an InP substrate, a GaN substrate, a SiC substrate, a sapphire substrate, or a ZnSe substrate), an SOI (silicon on insulator) substrate formed by a bonding method or a SIMOX (separation by implanted oxygen) method, or the like can be used.

An element isolation insulating film 504 isolates the transistors 501 and 502 from each other. For formation of the element isolation insulating film 504, a selective oxidation method (LOCOS (local oxidation of silicon) method), a trench isolation method, or the like can be used.

Further, a p-well 505 is formed in the semiconductor substrate 500 and the transistor 502 is formed using the p-well 505. Note that an example in which a single crystalline silicon substrate having n-type conductivity is used as the semiconductor substrate 500 and the p-well 505 is formed in the semiconductor substrate 500 is described in this embodiment. The p-well 505 in the semiconductor substrate 500 can be formed by introducing an impurity element which provides p-type conductivity into the semiconductor substrate 500 selectively. As the impurity element which provides p-type conductivity, boron (B), aluminum (Al), gallium (Ga), or the like can be used.

Note that, in this embodiment, an n-well is not formed in the region for forming the transistor 501 because the semiconductor substrate having n-type conductivity is used as the semiconductor substrate 500. However, an n-well may be formed in the region for forming the transistor 501 by introduction of an impurity element which provides n-type conductivity. As the impurity element which provides n-type conductivity, phosphorus (P), arsenic (As), or the like can be used.

Alternatively, in the case where a semiconductor substrate having p-type conductivity is used as the semiconductor substrate 500, an n-well may be formed by introducing an impurity element which provides n-type conductivity into the semiconductor substrate selectively. Then, the transistor 501 can be formed using the n-well.

A gate insulating film 506 is included in each of the transistors 501 and 502. In this embodiment, a silicon oxide film which is formed by thermal oxidization of the semiconductor substrate 500 is used as the gate insulating film 506. Further, a stacked layer of a silicon oxide film and a silicon oxynitride film may be used as the gate insulating film 506 as well, which is formed as follows: the silicon oxide film is formed by thermal oxidation and then the silicon oxynitride film is formed by nitriding a surface of the silicon oxide film with nitridation treatment. Alternatively, the gate insulating film 506 may be formed by plasma treatment instead of thermal oxidation. For example, by oxidizing or nitriding the surface of the semiconductor substrate 500 with high density plasma treatment, a silicon oxide (SiOₓ) film or a silicon nitride (SiNₓ) film can be formed as the gate insulating film 506.

Further, a conductive film 507 is formed over the gate insulating film 506 in each of the transistors 501 and 502. Described in this embodiment is an example in which the conductive film 507 is formed by sequentially stacking two layers of conductive films. The conductive film 507 may have a single layer structure of a conductive film or a staked-layer structure in which three or more layers of conductive films are stacked.

The conductive film 507 can be formed of tantalum (Ta), tungsten (W), titanium (Ti), molybdenum (Mo), aluminum (Al), copper (Cu), chromium (Cr), niobium (Nb), or the like, a film formed of an alloy containing any of the above-described metals as a main component, or a film formed of a compound containing any of the above-described metals. Alternatively, a semiconductor doped with an impurity element such as phosphorus which provides one conductivity type to a semiconductor film, such as polycrystalline silicon may be used. In this embodiment, the conductive film 507 has a stacked-layer structure of a conductive film of tantalum nitride and a conductive film of tungsten.

Further, a pair of impurity regions 509 which function as a source and drain region formed in the semiconductor substrate 500 is included in the transistor 501. A channel formation region of the transistor 501 is formed between the pair of impurity regions 509. As an impurity element, an impurity element which provides n-type conductivity or an impurity element which provides p-type conductivity is used. As the impurity element which provides n-type conductivity, phosphorus (P), arsenic (As), or the like can be used. As the impurity element which provides p-type conductivity, boron (B), aluminum (Al), gallium (Ga), or the like can be used. In this embodiment, boron (B) is used as the impurity element.

Further, a pair of impurity regions 508 which function as a source and drain region formed in the p-well 505 is included in the transistor 502. A channel formation region of the transistor 502 is formed between the pair of impurity regions 508. As an impurity element, an impurity element which provides n-type conductivity or an impurity element which provides p-type conductivity is used. As the impurity element which provides n-type conductivity, phosphorus (P), arsenic (As), or the like can be used. As the impurity element which provides p-type conductivity, boron (B), aluminum (Al), gallium (Ga), or the like can be used. In this embodiment, phosphorus (P) is used as the impurity element.

The insulating film 503 has openings so as to partially expose the gate insulating film 506. The insulating film 503 can be formed by the manufacturing method of an insulating film of the present invention, described in any of the above-described embodiment mode.

Note that, although the example in which the transistors 501 and 502 are directly covered with the insulating film 503 of a siloxane resin is described in this embodiment, the present invention is not limited to this structure. Before the insulating film 503 is formed, an insulating film for preventing penetration of an impurity such as alkali metal or alkaline earth metal into the transistors 501 and 502 may be formed. Specifically, it is preferable to use silicon nitride, silicon nitride oxide, silicon oxynitride, aluminum nitride, aluminum oxide, silicon oxide, or the like for the insulating film. In this case, the above-described insulating film capable of preventing impurity penetration is exposed at the openings in the insulating film 503.

Next, as shown in FIG. 17B, patterning of the gate insulating film 506 is performed to expose the impurity regions 508 and 509. This patterning can be performed by dry etching. Note that it is preferable to cover the insulating film 503 with a mask when patterning of the gate insulating film 506 is performed. Note that, in the case where the transistors 501 and 502 are covered with the above-described insulating film capable of preventing impurity penetration, patterning of the insulating film is also performed.

Next, as shown in FIG. 17C, conductive films 510 to 513 are formed so as to be in contact with the impurity regions 508 and 509 in the openings. In this embodiment, the gradient of the edge of each opening formed in the insulating film 503 can be suppressed. Therefore, extremely thinning or disconnecting due to a step of the conductive films 510 to 513 in the edge of each opening can be prevented. Accordingly, the reliability of a semiconductor device can be improved.

Note that each of the transistors 501 and 502 is not limited to the structure shown in this embodiment. For example, an inversely-staggered structure may be employed as well.

This embodiment can be implemented combining with any of the above-described embodiment modes as appropriate.

### Embodiment 2

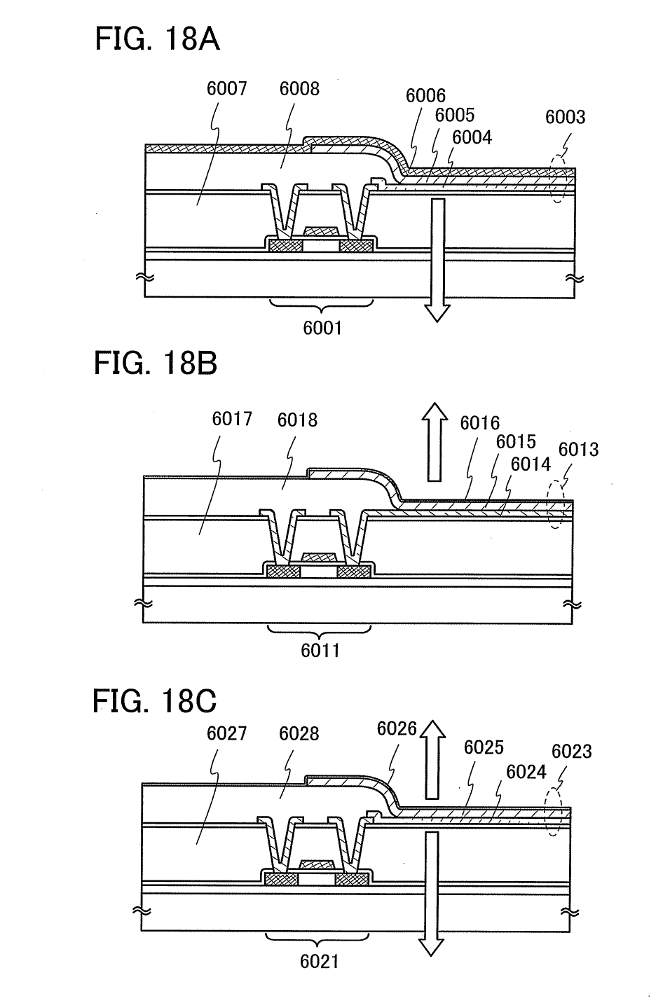

In this embodiment, a cross-sectional structure of a pixel in the case where a transistor for driving a light-emitting element is p-channel type is described using FIGS. 18A to 18C. Note that, although FIGS. 18A to 18C describe the case where a first electrode is an anode and a second electrode is a cathode, the first electrode may be a cathode and the second electrode may be an anode as well.

A cross-sectional diagram of a pixel in the case where a transistor 6001 is p-channel type, and light emitted from a light-emitting element 6003 is extracted from the first electrode 6004 side is shown in FIG. 18A.

The transistor 6001 is covered with an insulating film 6007, and over the insulating film 6007, a bank 6008 having an opening is formed. In the opening of the bank 6008, the first electrode 6004 is partially exposed, and the first electrode 6004, an electroluminescent layer 6005, and a second electrode 6006 are sequentially stacked in the opening.

The first electrode 6004 is formed of a material or to a thickness to transmit light, and formed of a material suitable for being used as an anode. For example, another light-transmitting oxide conductive material such as indium tin oxide (ITO), zinc oxide (ZnO), indium zinc oxide (IZO), or gallium-doped zinc oxide (GZO) can be used for the first electrode 6004. Alternatively, zinc oxide containing silicon oxide, indium tin oxide containing silicon oxide (hereinafter referred to as ITSO), or a mixture in which zinc oxide (ZnO) is mixed at 2 to 20 wt. % in ITSO may be used for the first electrode 6004. Further alternatively, other than the above-described light-transmitting oxide conductive material, a single-layer film containing one or more of titanium nitride, zirconium nitride, titanium, tungsten, nickel, platinum, copper, silver, aluminum, and the like, a stacked layer of a titanium nitride film and a film containing aluminum as a main component, a three-layer structure of a titanium nitride film, a film containing aluminum as a main component, and a titanium nitride film, or the like can be used for the first electrode 6004. However, in the case of using a material other than the light-transmitting oxide conductive material, the first electrode 6004 is formed to a thickness to transmit light (preferably, about 5 to 30 nm).

The second electrode 6006 is formed of a material and to a thickness to reflect or shied light, and can be formed of a material having a low work function of a metal, an alloy, an electrically conductive compound, a mixture thereof, or the like. Specifically, an alkaline metal such as Li or Cs, an alkaline earth metal such as Mg, Ca, or Sr, an alloy containing such metals (e.g., Mg:Ag, Al:Li, or Mg:In), a compound of such materials (e.g., calcium fluoride or calcium nitride), or a rare-earth metal such as Yb or Er can be used. Further, in the case where an electron injection layer is provided, another conductive layer such as an Al layer may be used as well.

The electroluminescent layer 6005 is formed of a single layer or a plurality of layers. When the electroluminescence layer 6005 is formed of a plurality of layers, the layers can be classified into a hole injection layer, a hole transport layer, a light-emitting layer, an electron transport layer, an electron injection layer, or the like in terms of the carrier transporting properties. In the case where the electroluminescent layer 6005 includes at least one of the hole injection layer, the hole transport layer, the electron transport layer, and the electron injection layer in addition to the light-emitting layer, the hole injection layer, the hole transport layer, the light-emitting layer, the electron transport layer, and the electron injection layer are sequentially stacked over the first electrode 6004. Note that the interface between the layers is not necessarily clear, and there might be the case where materials forming the layers are partially mixed and the interface between the layers is unclear. Each layer can be formed of an organic-based material or an inorganic-based material. As the organic-based material, any of a high molecular weight organic material, a medium molecular weight organic material, and a low molecular weight organic material can be used. Note that the medium molecular weight material corresponds to a low polymer in which the number of repetitions of a structural unit (the degree of polymerization) is about 2 to 20. There is no clear distinction between the hole injection layer and the hole transport layer. A layer being in contact with the anode is referred to as a hole injection layer and a layer being in contact with the hole injection layer is referred to as a hole transport layer for convenience. The same is also true for the electron transport layer and the electron injection layer; a layer being in contact with the cathode is referred to as an electron injection layer and a layer being in contact with the electron injection layer is referred to as an electron transport layer. In some cases, the light-emitting layer also functions as the electron transport layer, and it is therefore referred to as a light-emitting electron transport layer, too.

In the case of the pixel shown in FIG. 18A, light emitted from the light-emitting element 6003 can be extracted from the first electrode 6004 side as shown by a hollow arrow.

Next, a cross-sectional diagram of a pixel in the case where a transistor 6011 is p-channel type, and light emitted from a light-emitting element 6013 is extracted from the second electrode 6016 side is shown in FIG. 18B. The transistor 6011 is covered with an insulating film 6017, and over the insulating film 6017, a bank 6018 having an opening is formed. In the opening of the bank 6018, the first electrode 6014 is partially exposed, and a first electrode 6014, an electroluminescent layer 6015, and the second electrode 6016 are sequentially stacked in the opening.

The first electrode 6014 is formed of a material and to a thickness to reflect or shied light, and can be formed of a material suitable for being used as an anode. For example, a single-layer film containing one or more of titanium nitride, zirconium nitride, titanium, tungsten, nickel, platinum, copper, silver, aluminum, and the like, a stacked layer of a titanium nitride film and a film containing aluminum as a main component, a three-layer structure of a titanium nitride film, a film containing aluminum as a main component, and a titanium nitride film, or the like can be used for the first electrode 6014.

The second electrode 6016 is formed of a material or to a thickness to transmit light, and can be formed of a material having a low work function of a metal, an alloy, an electrically conductive compound, a mixture thereof, or the like. Specifically, an alkaline metal such as Li or Cs, an alkaline earth metal such as Mg, Ca, or Sr, an alloy containing such metals (e.g., Mg:Ag, Al:Li, or Mg:In), a compound of such materials (e.g., calcium fluoride or calcium nitride), or a rare-earth metal such as Yb or Er can be used. Further, in the case where an electron injection layer is provided, another conductive layer such as an Al layer may be used as well. Then, the second electrode 6016 is formed to a thickness to transmit light (preferably, about 5 to 30 nm). Note that another light-transmitting oxide conductive material can be used as well such as indium tin oxide (ITO), zinc oxide (ZnO), indium zinc oxide (IZO), gallium-doped zinc oxide (GZO), or the like. Further, zinc oxide containing silicon oxide, indium tin oxide containing silicon oxide (hereinafter referred to as ITSO), or a mixture in which zinc oxide (ZnO) is mixed at 2 to 20 wt. % in ITSO may be used as well. In the case of using the light-transmitting oxide conductive material, it is preferable to provide an electron injection layer in the electroluminescent layer 6015.

The electroluminescent layer 6015 can be formed in a similar manner to the electroluminescent layer 6005 of FIG. 18A.

In the case of the pixel shown in FIG. 18B, light emitted from the light-emitting element 6013 can be extracted from the second electrode 6016 side as shown by a hollow arrow.

Next, a cross-sectional diagram of a pixel in the case where a transistor 6021 is p-channel type, and light emitted from a light-emitting element 6023 is extracted from the first electrode 6024 side and the second electrode 6026 side is shown in FIG. 18C. The transistor 6021 is covered with an insulating film 6027, and over the insulating film 6027, a bank 6028 having an opening is formed. In the opening of the bank 6028, the first electrode 6024 is partially exposed, and the first electrode 6024, an electroluminescent layer 6025, and the second electrode 6026 are sequentially stacked in the opening.

The first electrode 6024 can be formed in a similar manner to the first electrode 6004 of FIG. 18A. The second electrode 6026 can be formed in a similar manner to the second electrode 6016 of FIG. 18B. The electroluminescent layer 6025 can be formed in a similar manner to the electroluminescent layer 6005 of FIG. 18A.

In the case of the pixel shown in FIG. 18C, light emitted from the light-emitting element 6023 can be extracted from the first electrode 6024 side and the second electrode 6026 side as shown by hollow arrows.

Note that the insulating film formed by the manufacturing method of the present invention is used as each of the banks 6008, 6018, and 6028, and the taper angle in the opening is smaller than that in an opening formed by dry etching and the flatness is higher. Therefore, extremely thinning or disconnecting due to a step of each of the electroluminescent layers 6005, 6015, and 6025 in the edge of the opening can be prevented. Therefore, the reliability of the light-emitting elements 6003, 9013, and 6023, and the reliability of semiconductor devices including any of the light-emitting elements 6003, 9013, and 6023 can be increased. Further, the problem in that hygroscopicity of an insulating film is increased by increase of OH radicals does not occur unlike the case of dry etching. Therefore, the deterioration of the light-emitting elements 6003, 9013, and 6023 can be suppressed by suppressing the hygroscopicity of the banks 6008, 6018, and 6028, whereby the reliability of a semiconductor device can be improved. Furthermore, since each of the banks 6008, 6018, and 6028 can be formed of a conventional non-photosensitive siloxane resin, an inexpensive raw material can be used, whereby the manufacturing cost of a semiconductor device can be suppressed.

This embodiment can be implemented combining with any of the above-described embodiment modes and embodiment as appropriate.

### Embodiment 3

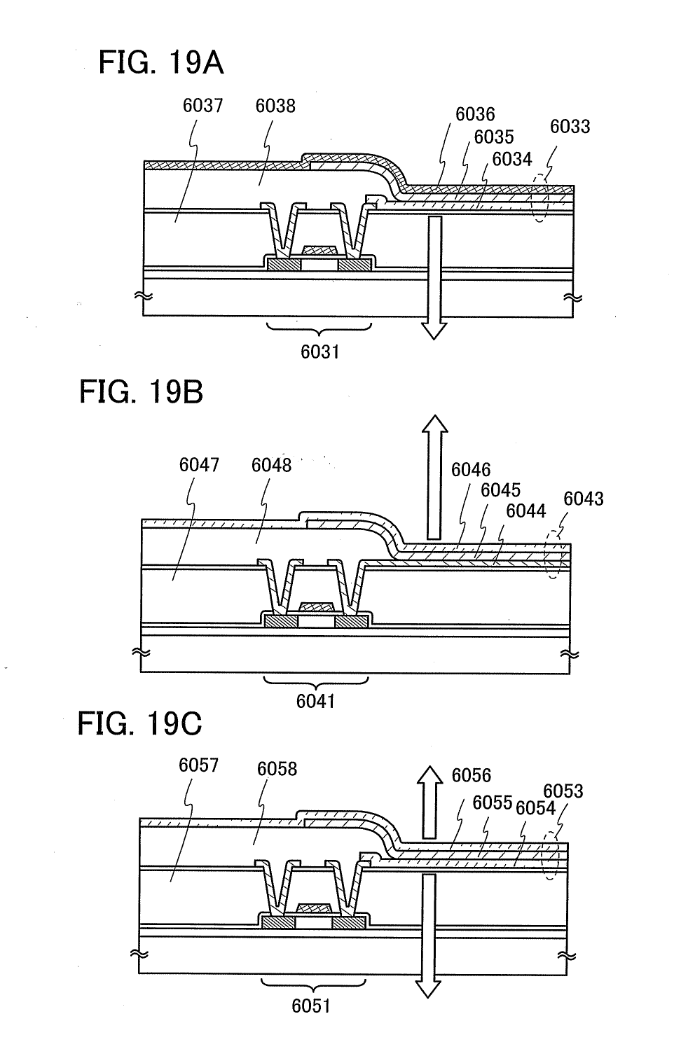

In this embodiment, a cross-sectional structure of a pixel in the case where a transistor for driving a light-emitting element is n-channel type is described using FIGS. 19A to 19C. Note that, although FIGS. 19A to 19C describe the case where a first electrode is a cathode and a second electrode is an anode, the first electrode may be an anode and the second electrode may be a cathode as well.

A cross-sectional diagram of a pixel in the case where a transistor 6031 is n-channel type, and light emitted from a light-emitting element 6033 is extracted from the first electrode 6034 side is shown in FIG. 19A. The transistor 6031 is covered with an insulating film 6037, and over the insulating film 6037, a bank 6038 having an opening is formed. In the opening of the bank 6038, the first electrode 6034 is partially exposed, and the first electrode 6034, an electroluminescent layer 6035, and a second electrode 6036 are sequentially stacked in the opening.

The first electrode 6034 is formed of a material or to a thickness to transmit light, and can be formed of a material having a low work function of a metal, an alloy, an electrically conductive compound, a mixture thereof, or the like. Specifically, an alkaline metal such as Li or Cs, an alkaline earth metal such as Mg, Ca, or Sr, an alloy containing such metals (e.g., Mg:Ag, Al:Li, or Mg:In), a compound of such materials (e.g., calcium fluoride or calcium nitride), or a rare-earth metal such as Yb or Er can be used. Further, in the case where an electron injection layer is provided, another conductive layer such as an Al layer may be used as well. Then, the first electrode 6034 is formed to a thickness to transmit light (preferably, about 5 to 30 nm). Furthermore, the sheet resistance of the first electrode 6034 may be suppressed by formation of a light-transmitting conductive layer of a light-transmitting oxide conductive material so as to be in contact with and over or under the above-described conductive layer with a thickness to transmit light. Alternatively, the first electrode 6034 may be formed of only a conductive layer of another light-transmitting oxide conductive material such as indium tin oxide (ITO), zinc oxide (ZnO), indium zinc oxide (IZO), or gallium-doped zinc oxide (GZO). Further, zinc oxide containing silicon oxide, indium tin oxide containing silicon oxide (hereinafter referred to as ITSO), or a mixture in which zinc oxide (ZnO) is mixed at 2 to 20 wt. % in ITSO may be used as well. In the case of using the light-transmitting oxide conductive material, it is preferable to provide an electron injection layer in the electroluminescent layer 6035.

The second electrode 6036 is formed of a material and to a thickness to reflect or shied light, and can be formed of a material suitable for being used as an anode. For example, a single-layer film containing one or more of titanium nitride, zirconium nitride, titanium, tungsten, nickel, platinum, copper, silver, aluminum, and the like, a stacked layer of a titanium nitride film and a film containing aluminum as a main component, a three-layer structure of a titanium nitride film, a film containing aluminum as a main component, and a titanium nitride film, or the like can be used for the second electrode 6036.

The electroluminescent layer 6035 can be formed in a similar manner to the electroluminescent layer 6005 of FIG. 18A. In the case where the electroluminescent layer 6035 includes at least one of a hole injection layer, a hole transport layer, an electron transport layer, and an electron injection layer in addition to a light-emitting layer, the electron injection layer, the electron transport layer, the light-emitting layer, the hole transport layer, and the hole injection layer are sequentially stacked over the first electrode 6034.

In the case of the pixel shown in FIG. 19A, light emitted from the light-emitting element 6033 can be extracted from the first electrode 6034 side as shown by a hollow arrow.

Next, a cross-sectional diagram of a pixel in the case where a transistor 6041 is n-channel type, and light emitted from a light-emitting element 6043 is extracted from the second electrode 6046 side is shown in FIG. 19B. The transistor 6041 is covered with an insulating film 6047, and over the insulating film 6047, a bank 6048 having an opening is formed. In the opening of the bank 6048, a first electrode 6044 is partially exposed, and the first electrode 6044, an electroluminescent layer 6045, and the second electrode 6046 are sequentially stacked in the opening.

The first electrode 6044 is formed of a material and to a thickness to reflect or shied light, and can be formed of a material having a low work function of a metal, an alloy, an electrically conductive compound, a mixture thereof, or the like. Specifically, an alkaline metal such as Li or Cs, an alkaline earth metal such as Mg, Ca, or Sr, an alloy containing such metals (e.g., Mg:Ag, Al:Li, or Mg:In), a compound of such materials (e.g., calcium fluoride or calcium nitride), or a rare-earth metal such as Yb or Er can be used. Further, in the case where an electron injection layer is provided, another conductive layer such as an Al layer may be used as well.

The second electrode 6046 is formed of a material or to a thickness to transmit light, and formed of a material suitable for being used as an anode. For example, another light-transmitting oxide conductive material such as indium tin oxide (ITO), zinc oxide (ZnO), indium zinc oxide (IZO), or gallium-doped zinc oxide (GZO) can be used for the second electrode 6046. Alternatively, zinc oxide containing silicon oxide, indium tin oxide containing silicon oxide (hereinafter referred to as ITSO), or a mixture in which zinc oxide (ZnO) is mixed at 2 to 20 wt. % in ITSO may be used for the second electrode 6046. Further alternatively, other than the above-described light-transmitting oxide conductive material, a single-layer film containing one or more of titanium nitride, zirconium nitride, titanium, tungsten, nickel, platinum, copper, silver, aluminum, and the like, a stacked layer of a titanium nitride film and a film containing aluminum as a main component, a three-layer structure of a titanium nitride film, a film containing aluminum as a main component, and a titanium nitride film, or the like can be used for the second electrode 6046. However, in the case of using a material other than the light-transmitting oxide conductive material, the second electrode 6046 is formed to a thickness to transmit light (preferably, about 5 to 30 nm).

The electroluminescent layer 6045 can be formed in a similar manner to the electroluminescent layer 6035 of FIG. 19A.

In the case of the pixel shown in FIG. 19B, light emitted from the light-emitting element 6043 can be extracted from the second electrode 6046 side as shown by a hollow arrow.

Next, a cross-sectional diagram of a pixel in the case where a transistor 6051 is n-channel type, and light emitted from a light-emitting element 6053 is extracted from the first electrode 6054 side and the second electrode 6056 side is shown in FIG. 19C. The transistor 6051 is covered with an insulating film 6057, and over the insulating film 6057, a bank 6058 having an opening is formed. In the opening of the bank 6058, the first electrode 6054 is partially exposed, and the first electrode 6054, an electroluminescent layer 6055, and the second electrode 6056 are sequentially stacked in the opening.

The first electrode 6054 can be formed in a similar manner to the first electrode 6034 of FIG. 19A. The second electrode 6056 can be formed in a similar manner to the second electrode 6046 of FIG. 19B. The electroluminescent layer 6055 can be formed in a similar manner to the electroluminescent layer 6035 of FIG. 19A.

In the case of the pixel shown in FIG. 19C, light emitted from the light-emitting element 6053 can be extracted from the first electrode 6054 side and the second electrode 6056 side as shown by hollow arrows.

Note that the insulating film formed by the manufacturing method of the present invention is used as each of the banks 6038, 6048, and 6058, and the taper angle in the opening is smaller than that in an opening formed by dry etching and the flatness is higher. Therefore, extremely thinning or disconnecting due to a step of each of the electroluminescent layers 6035, 6045, and 6055 in the edge of the opening can be prevented. Therefore, the reliability of the light-emitting elements 6033, 6043, and 6053, and the reliability of semiconductor devices including any of the light-emitting elements 6033, 6043, and 6053 can be increased. Further, the problem in that hygroscopicity of an insulating film is increased by increase of OH radicals does not occur unlike the case of dry etching. Therefore, the deterioration of the light-emitting elements 6033, 6043, and 6053 can be suppressed by suppressing the hygroscopicity of the banks 6038, 6048, and 6058, whereby the reliability of a semiconductor device can be improved. Furthermore, since each of the banks 6038, 6048, and 6058 can be formed of a conventional non-photosensitive siloxane resin, an inexpensive raw material can be used, whereby the manufacturing cost of a semiconductor device can be suppressed.

This embodiment can be implemented combining with any of the above-described embodiment modes and embodiments as appropriate.

This application is based on Japanese Patent Application Serial No. 2007045146 filed with Japan Patent Office on Feb. 26, 2007, the entire contents of which are hereby incorporated by reference.

What is claimed is:

1. A method for manufacturing a semiconductor device, comprising:
forming a thin film using a suspension in which a siloxane resin or a siloxane-based material is included in a first organic solvent;
performing a first heat treatment on the thin film;
forming a mask over the thin film after the first heat treatment;
performing wet etching with a second organic solvent on the thin film after the first heat treatment; and
performing a second heat treatment on the thin film after the wet etching.

2. The method for manufacturing the semiconductor device, according to claim 1, wherein the second organic solvent is alcohol in which the carbon number is in the range of 3 to 5.

3. The method for manufacturing the semiconductor device, according to claim 1, wherein the thin film is formed over a conductive film.

4. The method for manufacturing the semiconductor device, according to claim 3, wherein an opening is formed in the thin film by the wet etching so as to expose the conductive film.

5. A method for manufacturing a semiconductor device, comprising:
forming a thin film using a suspension in which a siloxane resin or a siloxane-based material is included in a first organic solvent;
performing a first heat treatment on the thin film;
forming a mask over the thin film after the first heat treatment;
performing wet etching with a second organic solvent on the thin film after the first heat treatment; and
performing a second heat treatment on the thin film after the wet etching, at a temperature which is higher than that of the first heat treatment.

6. The method for manufacturing the semiconductor device, according to claim 5, wherein the second organic solvent is alcohol in which the carbon number is in the range of 3 to 5.

7. The method for manufacturing the semiconductor device, according to claim 5, wherein the thin film is formed over a conductive film.

8. The method for manufacturing the semiconductor device, according to claim 7, wherein an opening is formed in the thin film by the wet etching so as to expose the conductive film.

9. A method for manufacturing a semiconductor device, comprising:
forming a thin film using a suspension in which a siloxane resin or a siloxane-based material is included in a first organic solvent;
performing a first heat treatment on the thin film at a temperature which is as high as the thin film is hardened and lower than a boiling point of the first organic solvent;
forming a mask over the thin film after the first heat treatment;
performing wet etching with a second organic solvent on the thin film after the first heat treatment; and
performing a second heat treatment on the thin film after the wet etching, at a temperature which is higher than the boiling point of the first organic solvent.

10. The method for manufacturing the semiconductor device, according to claim 9, wherein the first heat treatment is performed at the temperature lower than the boiling point of the first organic solvent such that the period of time up to completion of the wet etching is 30 seconds or longer.

11. The method for manufacturing the semiconductor device, according to claim 9, wherein the second organic solvent is alcohol in which the carbon number is in the range of 3 to 5.

12. The method for manufacturing the semiconductor device, according to claim 9, wherein the thin film is formed over a conductive film.

13. The method for manufacturing the semiconductor device, according to claim 12, wherein an opening is formed in the thin film by the wet etching so as to expose the conductive film.

14. A method for manufacturing a semiconductor device, comprising:
forming a thin film using a suspension in which a siloxane resin or a siloxane-based material is included in a first organic solvent;
performing a first heat treatment on the thin film;
forming a mask over the thin film after the first heat treatment;
performing a second heat treatment on the thin film after the mask is formed;
performing wet etching with a second organic solvent on the thin film after the second heat treatment; and
performing a third heat treatment on the thin film after the wet etching.

15. The method for manufacturing the semiconductor device, according to claim 14, wherein the second organic solvent is alcohol in which the carbon number is in the range of 3 to 5.

16. The method for manufacturing the semiconductor device, according to claim 14, wherein the thin film is formed over a conductive film.

17. The method for manufacturing the semiconductor device, according to claim 16, wherein an opening is formed in the thin film by the wet etching so as to expose the conductive film.

18. A method for manufacturing a semiconductor device, comprising:
forming a thin film using a suspension in which a siloxane resin or a siloxane-based material is included in a first organic solvent;
performing a first heat treatment on the thin film;
forming a mask over the thin film after the first heat treatment;
performing a second heat treatment on the thin film after the mask is formed;
performing wet etching with a second organic solvent on the thin film after the second heat treatment; and
performing a third heat treatment on the thin film after the wet etching, at a temperature which is higher than that of the second heat treatment.

19. The method for manufacturing the semiconductor device, according to claim 18, wherein the second organic solvent is alcohol in which the carbon number is in the range of 3 to 5.

20. The method for manufacturing the semiconductor device, according to claim 18, wherein the thin film is formed over a conductive film.

21. The method for manufacturing the semiconductor device, according to claim 20, wherein an opening is formed in the thin film by the wet etching so as to expose the conductive film.

22. A method for manufacturing a semiconductor device, comprising:
forming a thin film using a suspension in which a siloxane resin or a siloxane-based material is included in a first organic solvent;
performing a first heat treatment on the thin film at a temperature which is as high as the thin film is hardened;
forming a mask over the thin film after the first heat treatment;
performing a second heat treatment on the thin film after the mask is formed, at a temperature which is higher than that of the first heat treatment;
performing wet etching with a second organic solvent on the thin film after the second heat treatment; and
performing a third heat treatment on the thin film after the wet etching, at a temperature which is higher than a boiling point of the first organic solvent,
wherein the second heat treatment is performed at a temperature which is lower than a boiling point of the first organic solvent.

23. The method for manufacturing the semiconductor device, according to claim 22, wherein the second heat treatment is performed at the temperature lower than the boiling point of the first organic solvent such that the period of time up to completion of the wet etching is 30 seconds or longer.

24. The method for manufacturing the semiconductor device, according to claim 22, wherein the second organic solvent is alcohol in which the carbon number is in the range of 3 to 5.

25. The method for manufacturing the semiconductor device, according to claim 22, wherein the thin film is formed over a conductive film.

26. The method for manufacturing the semiconductor device, according to claim 25, wherein an opening is formed in the thin film by the wet etching so as to expose the conductive film.
